(19) United States
(12) Patent Application Publication
(10) Pub. No.: US 2024/0229282 A1
(43) Pub. Date: Jul. 11, 2024

(54) PROCESS FOR HYSTERETIC CURRENT-VOLTAGE MEDIATED VOID-FREE SUPERCONFORMAL AND BOTTOM-UP FILLING

(71) Applicant: Government of the United States of America, as represented by the Secretary of Commerce, Gaithersburg, MD (US)

(72) Inventors: Trevor Michael Braun, San Francisco, CA (US); Thomas Polk Moffat, Gaithersburg, MD (US); Daniel Josell, Potomac, MD (US)

(21) Appl. No.: 18/558,324

(22) PCT Filed: May 12, 2022
(86) PCT No.: PCT/US22/28946

§ 371 Date: Oct. 31, 2023

Related U.S. Application Data
(60) Provisional application No. 63/187,509, filed on May 12, 2021.

(51) Int. Cl. C25D 5/18; C25D 3/38; H01L 21/288; H01L 21/768

(52) U.S. Cl. CPC C25D 5/18; C25D 3/38; H01L 21/2885; H01L 21/76898

(57) ABSTRACT

Hysteretic current-voltage mediated void-free superconformal and bottom-up filling of recessed features includes providing an electrodeposition composition with a hysteretic cyclic voltammogram; providing the substrate controlling applied electric potential; autonomously reducing the deposition potential of the recess; bifurcating the recess; forming a transition zone and moving the transition zone through the metal deposition; and reducing metal ions to form metal; and forming a resistance enhanced superconformal filling in the recess from the metal, such that forming the resistance enhanced superconformal filling occurs in consequence of autonomously reducing the deposition potential of the recess.

### CROSS REFERENCE TO RELATED APPLICATIONS

This application claims the benefit of U.S. Provisional Patent Application Ser. No. 63/187,509 (filed May 12, 2021), which is herein incorporated by reference in its entirety.

### STATEMENT REGARDING FEDERALLY SPONSORED RESEARCH

This invention was made with United States Government support from the National Institute of Standards and Technology (NIST), an agency of the United States Department of Commerce. The Government has certain rights in this invention.

### BRIEF DESCRIPTION

Disclosed is a process for performing hysteretic current-voltage mediated void-free superconformal and bottom-up filling of recessed features of a substrate with a resistance member, the process comprising: providing an electrodeposition composition comprising: a metal electrolyte comprising a plurality of metal ions and a solvent; and a suppressor disposed in the solvent; and a hysteretic cyclic voltammogram; providing the substrate comprising: a field surface; and the recess disposed in the substrate, the recess comprising a distal position and a proximate position relative to the field surface of the substrate; exposing the recess to the electrodeposition composition; potentiostatically or potentiodynamically controlling an applied electric potential of the recess with a potential wave form; autonomously reducing, with the resistance member in presence of the electrodeposition composition with the hysteretic cyclic voltammogram, the deposition potential of the recess from that applied by the potential waveform; bifurcating the recess into an active metal deposition region and a passive region in response to the deposition potential and ohmic variations of the substrate; forming, in response to bifurcating the recess, a transition zone at an interface of the active metal deposition region and the passive region; progressively moving the transition zone closer to the field surface and away from the distal position through the metal deposition; and reducing the metal ions to form metal and depositing the metal in the active metal deposition region and not in the passive region; and forming a resistance enhanced superconformal filling in the recess of the substrate from the metal in the active metal deposition region, the resistance enhanced superconformal filling being: void-free, disposed in the recess in the active metal deposition region from the distal position to the transition zone, and absent in the passive region between the proximate position and the transition zone, such that forming the resistance enhanced superconformal filling occurs in consequence of autonomously reducing the deposition potential of the recess with the resistance member in a presence of the hysteretic cyclic voltammogram of the electrodeposition composition.

Disclosed is a system for performing hysteretic current-voltage mediated void-free superconformal and bottom-up filling of recessed features of a substrate with a resistance member, the system comprising: a cell; an electrodeposition composition disposed in the cell and comprising: a metal electrolyte comprising a plurality of metal ions and a solvent; and a suppressor disposed in the solvent; and a hysteretic cyclic voltammogram; the substrate disposed in the cell in fluid communication with the electrodeposition composition and comprising: a field surface; and the recess disposed in the substrate, the recess comprising a distal position and a proximate position relative to the field surface of the substrate, such that the recess is in contact with the electrodeposition composition, such that an applied electric potential of the recess is under potentiostatically or potentiodynamically control with a potential wave form; the resistance member in communication with the electrodeposition composition and the substrate, wherein the apparatus is arranged and configured such that the resistance member in presence of the electrodeposition composition with the hysteretic cyclic voltammogram: autonomously reduces the deposition potential of the recess from that applied by the potential waveform, such that the recess is bifurcated into an active metal deposition region and a passive region in response to the deposition potential and ohmic variations of the substrate; whereby, in response to bifurcating the recess, a transition zone is formed at an interface of the active metal deposition region and the passive region, such that the transition zone progressively moves closer to the field surface and away from the distal position through the metal deposition to reduce the metal ions and form metal to deposit the metal in the active metal deposition region and not in the passive region; thereby forming a resistance enhanced superconformal filling in the recess of the substrate from the metal in the active metal deposition region, wherein the resistance enhanced superconformal filling is void-free, disposed in the recess in the active metal deposition region from the distal position to the transition zone, and absent in the passive region between the proximate position and the transition zone, such that forming the resistance enhanced superconformal filling occurs in consequence of autonomously reducing the deposition potential of the recess with the resistance member in a presence of the hysteretic cyclic voltammogram of the electrodeposition composition.

### BRIEF DESCRIPTION OF THE DRAWINGS

The following description cannot be considered limiting in any way. Various objectives, features, and advantages of the disclosed subject matter can be more fully appreciated with reference to the following detailed description of the disclosed subject matter when considered in connection with the following drawings, in which like reference numerals identify like elements.

FIG. 1 shows several substrates, according to some embodiments.

FIG. 2 shows a formation of a resistance enhanced superconformal filling disposed in a substrate, according to some embodiments.

FIG. 3 shows a formation of a resistance enhanced superconformal filling disposed in a substrate, according to some embodiments.

FIG. 4 shows comparative deposition of metal in a substrate, according to some embodiments.

FIG. 5 shows comparative deposition of metal in a substrate, according to some embodiments.

FIG. 6 shows comparative deposition of metal in a substrate, according to some embodiments.

FIG. 7 shows comparative metal disposed in a substrate, according to some embodiments.

FIG. 8 shows a graph of current density versus potential for a cyclic voltammogram having an S-shaped negative differential resistance (S-NDR) in panel A, and panel B shows a graph of current density versus deposition potential for a cyclic voltammogram having an N-shaped negative differential resistance (N-NDR), according to some embodiments.

FIG. 9 shows experimental and simulated voltammetry of Co deposition in electrolytes with the indicated polyethyleneimine (PEI) additive concentrations at the indicated rotating disk electrode (RDE) rotation rates with simulations of the negative-going sweeps, all plotted against the applied potential, according to some embodiments.

FIG. 10 Panel A shows cyclic voltammetry for Ni deposition in electrolyte with different concentrations of 1800 molecular weight (MW) PEI with partial correction of the electrical resistance of the deposition system. FIG. 10 Panel B shows the data fully corrected for the system resistance, according to some embodiments.

FIG. 11 Panel A shows cyclic voltammetry of Co deposition in electrolyte containing 5 μmol/L branched PEI with one scan collected without compensation for system resistance plotted against both the applied potential and the potential corrected for the potential drop. Panel B shows the same data replotted to emphasize the hysteretic range and S-shaped NDR, according to some embodiments.

FIG. 12 shows cross-sectioned annular through silicon vias (TSVs) after 10 minutes of Ni deposition, wherein an impact of increasing PEI concentration is shown from left to right, and the effect of increasing deposition overpotential from bottom to top, according to some embodiments.

FIG. 13 shows cross-sectioned annular TSVs after Co deposition in electrolyte containing 20 μmol/L PEI, wherein start and stop potentials are indicated for deposition starting at −1.19 V and proceeding in −20 mV increments to the indicated stop potential; the dwell time increment at each potential step is indicated, according to some embodiments.

FIG. 14 shows representative arrays of TSVs after 12 minutes of Cu deposition at the indicated potentials in electrolyte containing 12 μmol/L suppressor. Suppression breakdown within the vias at −0.58 V yields a bimodal distribution of filling heights, according to some embodiments.

FIG. 15 shows a schematic of an electrodeposition cell including substrate in electrolyte, counter electrode and reference electrode immersed in electrolyte with a potentiostat connected to the substrate with a permeable or semipermeable resistive baffle or membrane in the electrolyte between the reference electrode and the substrate. An additional resistance can be generated by increasing a distance between the reference electrode and the work piece (also referred to the substrate, according to some embodiments.

FIG. 16 shows a schematic of an electrodeposition cell including substrate in electrolyte, counter electrode and reference electrode immersed in electrolyte with a potentiostat connected to the substrate through an external electrical resistance electrically interposed between the power supply or potentiostat and substrate, according to some embodiments.

FIG. 17 shows (a) a schematic of the axisymmetric geometry used in the S-NDR model to simulate deposition in the annular TSV. (b) Simulated growth contours in 6 min intervals (left-hand via) and final deposit positions (right-hand via) for potentiostatic (top) and galvanostatic (bottom) copper electrodeposition after 1 h at the indicated operating conditions of applied potential or fixed current. (c) Current and (d) overpotential (applied potential minus reversible potential for the metal deposition reaction, η) transients for the indicated simulations presented in (b), according to some embodiments.

FIG. 18 shows simulated growth contours in 6 min intervals (left-hand via) and final interface positions (right-hand via) for potentiostatic copper deposition in the annular via at the indicated potentials with a total resistance equivalent to (a) 11× and (b) 41× the original cell resistance of 1 Ωs. Schematics show a 1-D representation of the resistances in the circuit. Corresponding (c) current and (d) overpotential transients are included for the characteristic deposition profiles, according to some embodiments.

FIG. 19 Panel (a) shows the lowest position of the copper deposit on the annular TSV interface after 1 h of deposition as a function of applied potential for the indicated system resistance. The dashed line represents the deposit height for a fully filled via. FIG. 19 Panel (b) shows the time needed for filling along the centerline to reach 90% of the via height plotted as a function of applied potential for the indicated uncompensated cell resistance, according to some embodiments.

FIG. 20 shows (a) a schematic of the axisymmetric geometry used in the S-NDR model to simulate deposition in a cylindrical TSV. Simulated growth profiles for (b) potentiostatic and (c) galvanostatic copper electrodeposition after 1 h at the indicated applied potentials and currents with 1 Ωs of uncompensated resistance and simulated growth profiles after 1 h of potentiostatic copper electrodeposition with the indicated system (i.e., cell) resistance, according to some embodiments.

FIG. 21 shows simulated growth contours for cylindrical TSV with three different heights for the indicated applied potentials/current and system resistance. The specified applied potentials are the most negative values that do not result in seam or void formation, according to some embodiments.

FIG. 22 shows the lowest centerline position of the copper deposit on the cylindrical TSV interface as a function of applied potential for the indicated system resistances and deposition times for TSV of the three indicated heights, according to some embodiments.

FIG. 23 shows (a) schematic of the 2-D geometry used in the S-NDR model to simulate deposition in trench arrays. Simulated growth profiles for (b) galvanostatic and (c) potentiostatic copper electrodeposition at the indicated operating conditions and final times with a system resistance of 11 Ωs. Contour lines represent the individual trench centerline positions of the electrode interface, spaced in 10 min intervals. (d-e) Charts showing the centerline position of the growth front for each individual trench as time progresses including when all trenches reach y=0, according to some embodiments.

FIG. 24 shows global current responses during galvanostatic and potentiostatic deposition for the indicated conditions with a system resistance of 11 Ωs for arrays of the indicated numbers of trenches. Galvanostatic currents scale with the number of trenches, according to some embodiments.

FIG. 25 shows simulated growth profiles for galvanostatic and potentiostatic copper electrodeposition at the indicated operating conditions, final times, and system resistances in an array of trenches having different widths. Contour lines represent the position of the growth front, spaced in 10 min intervals. Charts show the centerline position of the growth front of each individual trench as time progresses including when all trenches reach y=0, according to some embodiments.

FIG. 26 shows simulated growth profiles for galvanostatic and potentiostatic copper electrodeposition at the indicated operating conditions, uncompensated cell resistance and final times in an array of trenches having different heights. Contour lines represent the position of the growth front, spaced in 10 min intervals. Charts show the centerline position of the growth front for each individual trench as time progresses with including when all trenches reach y=0, according to some embodiments.

FIG. 27 shows parameters for mm-TSV simulations, according to some embodiments.

### DETAILED DESCRIPTION

A detailed description of one or more embodiments is presented herein by way of exemplification and not limitation.

It has been discovered that addition of an appropriate electrical resistance along a current path from a potentiostat to a substrate and then to a reference electrode through an electrodeposition composition provides a process for forming a resistance enhanced superconformal filling in a recess of a substrate in which metal deposition fills a recess on the substrate from a distal position such that the superconformal filling is a void-free, seam-free metallic filling.

A resistance enhanced superconformal filling can fill multiple recesses including recesses of different sizes on the same substrate seam-free and void-free using a single potential or a potential waveform within a broad potential window. The recess or recesses can be a tall and narrow high aspect ratio features such as a through hole (e.g., a through hole on a printed circuit board or a pinhole in a tube) or a blind hole in the substrate (e.g., a through silicon via in a silicon computer chip or a metal tube in a steam boiler). The process includes a suppressor in an electrodeposition composition that yields an hysteretic S-shaped negative differential resistance (S-NDR) current response during a voltage cycle of an electrodeposition such that both an active deposition rate of the metal and a passive deposition rate of the metal occur over a range of potential at the substrate (substrate potential) that is related to a type and a bulk concentration of the suppressor in the electrodeposition composition.

Beneficially, during filling of a recess the concentration of suppressor decreases from the field surface toward the distal position. Further, at a deposition potential in the range of potentials exhibiting the hysteretic current response (hysteretic range) active deposition of metal begins only in the recess from the distal position of the recess to a transition zone where a concentration of the suppressor is less than a critical concentration (CC). The critical concentration CC of the suppressor increases toward the bulk concentration at more negative values of the deposition potential within the hysteretic range. Accordingly, for a selected deposition potential in the hysteretic range, the decrease of suppressor concentration in a recess away from a field surface of a substrate provides deposition of the metal that can progress from the distal position to the transition zone, and the transition zone can progress toward the field surface.

Unexpectedly and advantageously, use of an electrical resistance in series with the deposition current allows void-free and seam-free filling of different diameter as well as different depth recesses to occur sequentially, simultaneously, or a combination thereof under a fixed applied potential and over a broad potential window because the deposition potential is altered from the applied potential in a time-dependent and feature size dependent manner by a resistive drop due to a deposition current associated with metal deposition (deposition current) across the electrical resistance.

For some electrodeposition compositions, suppressors, or substrate potentials, active metal deposition continues until reaching a position where a local concentration of the suppressor equals CC. For this subset active deposition in the recess halts at this position, i.e., deposition self-passivates. A more negative deposition potential within the hysteretic potential range corresponds to a more proximal position to which the transition zone can progress within the recess that is closer to the field surface and farther from the distal position.

It is contemplated that electrodeposition for filling high aspect ratio features relies on a variety of additives that selectively suppress deposition towards the top of the feature while permitting growth at the bottom. For additive packages consisting of a suppressor, localization of deposition is dictated by selective breakdown of the suppressor adlayer. Breakdown is associated with positive feedback and S-NDR in the global i-V response with characteristic features and deposit pattern formation influenced by the resistance of the electrochemical cell and operation mode of the electrochemical cell (potentiostatic or galvanostatic).

An external resistor and potentiostatic control can produce a filling dynamic that blends features of galvanostatic and external resistor-free potentiostatic deposition. Complete filling of features at a single potential followed by spontaneous interface passivation can occur. The extent of which depends on the magnitude of external resistance added to the cell.

In an embodiment, a process for performing hysteretic current-voltage mediated void-free superconformal and bottom-up filling of recessed features of a substrate with a resistance member, the process includes: providing an electrodeposition composition including: a metal electrolyte comprising a plurality of metal ions and a solvent; and a suppressor disposed in the solvent; and a hysteretic cyclic voltammogram; providing the substrate including: a field surface; and the recess disposed in the substrate, the recess comprising a distal position and a proximate position relative to the field surface of the substrate; exposing the recess to the electrodeposition composition; potentiostatically or potentiodynamically controlling an applied electric potential of the recess with a potential wave form; autonomously reducing, with the resistance member in presence of the electrodeposition composition with the hysteretic cyclic voltammogram, the deposition potential of the recess from that applied by the potential waveform; bifurcating the recess into an active metal deposition region and a passive region in response to the deposition potential and ohmic variations of the substrate; forming, in response to bifurcating the recess, a transition zone at an interface of the active metal deposition region and the passive region; progressively moving the transition zone closer to the field surface and away from the distal position through the metal deposition; and reducing the metal ions to form metal and depositing the metal in the active metal deposition region and not in the passive region; and forming a resistance enhanced superconformal filling in the recess of the substrate from the metal in the active metal deposition region, the resistance enhanced superconformal filling being: void-free, disposed in the recess in the active metal deposition region from the distal position to the transition zone, and absent in the passive region between the proximate position and the transition zone, such that forming the resistance enhanced superconformal filling occurs in consequence of autonomously reducing the deposition potential of the recess with the resistance member in a presence of the hysteretic cyclic voltammogram of the electrodeposition composition.

In an embodiment, the resistance member consists essentially of a lumped resistor, a baffle, and a selected interelectrode separation distance between the substrate and a reference electrode in electrical communication with the electrodeposition composition. In some embodiments, the resistance member is the lumped resistor, and the lumped resistor includes a resistor in electrical communication with and electrically interposed between the substrate and a counter electrode in electrical communication with the electrodeposition composition. In an embodiment, the resistance member is the baffle, and the baffle is in fluid communication with and fluidically interposed between the substrate and the reference electrode. According to an embodiment, the resistance member is the selected interelectrode separation distance between the substrate and a reference electrode in electrical communication with the electrodeposition composition, and the process further comprises adjusting the interelectrode separation.

The electrical resistance provided by lumped resistor 400 is in series between potentiostat 100 and substrate 2 and is summed with electrical resistance between reference electrode 500 and substrate 2. When present, for the latter, this includes baffle 450 and electrical resistance of the electrodeposition composition 300 between substrate 2 and reference electrode 500. The current distribution that defines the electrolyte resistance can be influenced by the overall distribution of current flowing from substrate 2 to counter electrode 700.

The process can include terminating the depositing the metal before completely filling the recess to the field surface or terminating depositing the metal after completely filling the recess to the field surface.

In an embodiment, the hysteretic cyclic voltammogram comprises an S-shaped negative differential resistance.

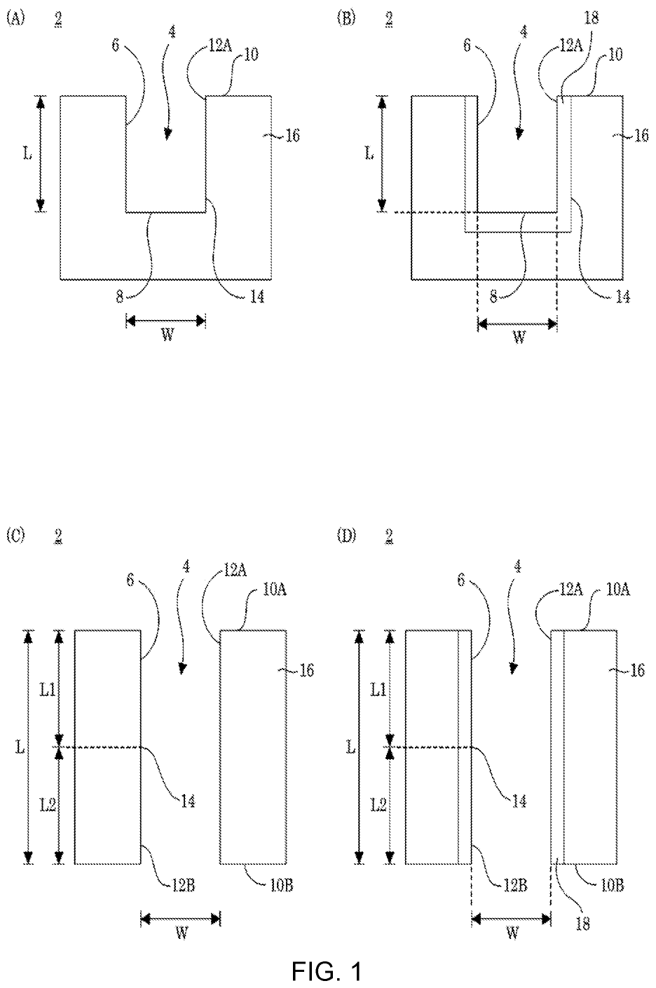

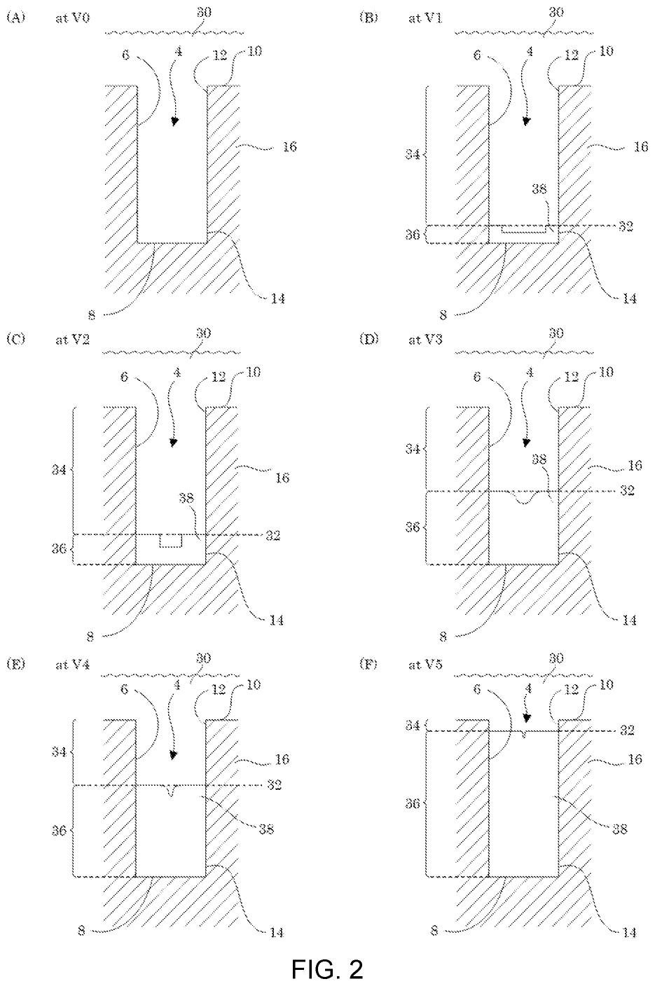

In an embodiment, with reference to FIG. 1, which shows cross-sections of substrate 2, substrate 2 includes recess 4 disposed in body member 16 and bounded by wall 6 and terminal wall 8 as shown in panel A. Recess 4 extends from proximate position 12 proximate to field surface 10 of body member 16 to distal position 14 distal to field surface 10 but proximate to terminal wall 8. Accordingly, recess 4 has a depth L from field surface 10 to terminal wall 8 and width W. In an embodiment, as shown in panel F of FIG. 2, resistance enhanced superconformal filling 38 is disposed in recess 4 of substrate 2. Formation of resistance enhanced superconformal filling 38 in recess 4 occurs via electrodeposition of metal. Here, wall 6 and terminal wall 8 are electrically conductive. It is contemplated that body member 16 is electrically conductive to provide electrical conductivity to wall 6 and terminal wall 8. In this configuration, recess 4 includes a blind hole.

According to an embodiment, with reference to panel B of FIG. 1, substrate 2 includes body member 16, electrically conductive layer 18 that is recessed with respect to field surface 10, recess 4 bounded by wall 6 and terminal wall 8. Here, body member can be an electrical conductor, electrical semiconductor, or electrical insulator, and electrically conductive layer 18 is electrically conductive to support electrodeposition of resistance enhanced superconformal filling 38 in recess 4.

In an embodiment, as shown in panel C of FIG. 1, recess 4 includes a through hole that extends from first field surface 10A to second field surface 10B. Proximate positions (12A, 12B) are proximate to field surfaces (10A, 10B). Distal position 14 is interposed between proximate positions (12A, 12B) and bisects recess 4. Accordingly, a distance between first field surface 10A and distal position 14 is first length L1. A distance between second field surface 10B and distal position 14 is second length L2, wherein total length L of recess 4 is a sum of first length L1 and second length L2. Moreover, as shown in panel D of FIG. 1, substrate 2 can include electrically conductive layer 18 disposed in body member 16 to provide wall 6 for recess 4.

In an embodiment, with reference to FIG. 2, panels A to F show formation of resistance enhanced superconformal filling 38 in recess 4 of substrate 2 as a function of time and deposition potential of wall 6 and terminal wall 8. At time t0 an applied voltage V0 is first applied by a potentiostat that is connected through an external resistance R to contact substrate 2 that includes body member 16 such that wall 6 and terminal wall 8 of body member 16 which are exposed to electrodeposition composition 30. Because a deposition current i has been zero there has been no current i passing through the external resistance so the deposition potential on the substrate is not reduced from the applied voltage by potential drop across the resistance that equals current multiplied by resistance (iR). As shown in panel B of FIG. 2, at time t1 thereafter, the deposition potential on the substrate 2 is now reduced from the potential V0 supplied by the potentiostat to a less negative voltage V1 due to potential drop across R from the now non-zero deposition current i passing through it, passive region 34 and active metal deposition region 36 are formed at wall 6 and terminal wall 8 with transition zone 32 interposed at an interface of passive region 34 and active metal deposition region 36. In this manner, recess 4 is bifurcated into active metal deposition region 36 and passive region 34 in response to resistance controlled deposition potential. As a result, metal ions in electrodeposition composition 30 are reduced and form metal that is deposited on wall 6 and terminal wall 8 in active metal deposition region 36 but not deposited in passive region 34. Further, resistance enhanced superconformal filling 38 is void-free, disposed in recess 4 in active metal deposition region 36 from the distal position 14 to transition zone 32, and absent in passive region 34 between proximate position 12 and transition zone 32. Thereafter, with reference to panel C of FIG. 2, at time t2, the deposition potential remains near or at voltage V1 as metal is produced from reduction of the metal ions in electrodeposition composition 30 so that transition zone 32 progressively moves toward field surface 10 and away from distal position 14. The metal is deposited in recess 4 on wall 6 and terminal wall 8 in active metal deposition region 36 but not deposited in passive region 34 as resistance enhanced superconformal filling 38 is enlarged to fill more of the volume of recess 4 from transition zone 32 to distal position 14.

With reference to panel D of FIG. 2, at time t3, the deposition potential still remains close to voltage V1 as the transition zone 32 progressively moves closer to field surface 10 and away from distal position 14. More metal is produced from reduction of the metal ions in electrodeposition composition 30. The metal is deposited in recess 4 on wall 6 and terminal wall 8 in active metal deposition region 36 but not deposited in passive region 34 as resistance enhanced superconformal filling 38 is enlarged to fill more of the volume of recess 4 from transition zone 32 to distal position 14. With reference to panel E of FIG. 2, at time t4, the deposition potential V2 begins to shift back more significantly from V1 toward V0 as suppressor concentration from the distal position 14 increases toward a bulk concentration existing outside the recess that begins to decrease the deposition current, so that the deposition potential V2 is at a potential between V1 and V0, and transition zone 32 progressively moves closer to field surface 10 and away from distal position 14. More metal is produced from reduction of the metal ions in electrodeposition composition 30. The metal is deposited in recess 4 on wall 6 and terminal wall 8 in active metal deposition region 36 but not deposited in passive region 34 as resistance enhanced superconformal filling 38 is enlarged to fill more of the volume of recess 4 from transition zone 32 to distal position 14. With reference to panel F of FIG. 2, at time t5, for the subset that self-passivates, the deposition potential reverts to the applied voltage V0 as transition zone 32 approaches close enough to field surface 10 and away from distal position 14 that the suppressor concentration reaches the critical concentration CC associated with the applied potential V0 and active deposition halts. Outside this subset, deposition can continue, including over and onto the field surface (10). In either manner resistance enhanced superconformal filling 38 is formed to be disposed in recess 4 of substrate 2.

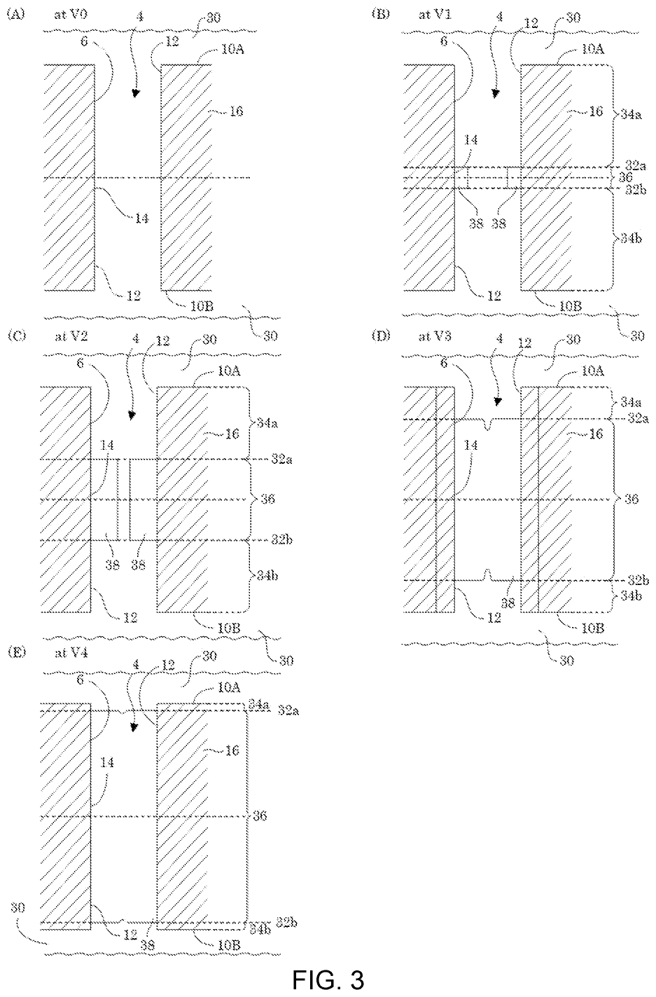

FIG. 3 shows formation of resistance enhanced superconformal filling 38 disposed in recess 4 of substrate 2, wherein recess 4 includes a through hole in body member 16. Here, substrate 2 also includes first field surface 10A and second field surface 10B, distal position 14 of recess 4 interposed between field surfaces (10A, 10B). As shown in panel A, at time t0 and supplied voltage V0, electrodeposition composition 30 is provided to contact substrate 2 such that wall 6 of body member 16 is exposed to electrodeposition composition 30. As shown in panel B of FIG. 3, at time t1, the deposition potential is reduced to voltage V1 from the potential V0 supplied by the potentiostat due to iR potential drop across the electrical resistance; and recess 4 is bifurcated into passive regions (34a, 34b), active metal deposition region 36 at wall 6 with transition zones (32a, 32b) interposed at interfaces of passive regions (34a, 34b) and active metal deposition region 36 as a result of differing suppressor concentrations within the feature and S-NDR nature of the electrodeposition composition. As a result, metal ions in electrodeposition composition 30 are reduced and form metal that is deposited as resistance enhanced superconformal filling 38 on wall 6 in active metal deposition region 36 but not deposited in passive regions (34a, 34b). Further, resistance enhanced superconformal filling 38 is void-free, disposed in recess 4 in active metal deposition region 36 from the distal position 14 to transition zones (32a, 32b), and absent in passive regions (34a, 34b) between proximate positions (12a, 12b) and transition zones (32a, 32b). Thereafter, with reference to panel C of FIG. 3, at time t2, the deposition potential may change to voltage V2 due to change of the deposition current with changing active area and resulting change of the iR potential drop, and transition zones (32a, 32b) progressively move closer to field surfaces (10a, 10b) and away from distal position 14 in response to metal deposition. More, metal is produced from reduction of the metal ions in electrodeposition composition 30. The metal is deposited in recess 4 on wall 6 in active metal deposition region 36 but not deposited in passive regions (34a, 34b) as resistance enhanced superconformal filling 38 is enlarged to fill more of the volume of recess 4 from transition zones (32a, 32b) to distal position 14.

With reference to panel D of FIG. 3, at time t3, the deposition potential voltage V3 is modified from the applied potential by variations of the ohmic losses as active deposition is maintained given change of active surface area as well as higher suppressor concentrations nearer to the field surface, and transition zones (32a, 32b) progressively move closer to field surfaces (10a, 10b) and away from distal position 14 due to metal deposition. More metal is produced from reduction of the metal ions in electrodeposition composition 30. The metal is deposited in recess 4 on wall 6 in active metal deposition region 36 but not deposited in passive region 34 as resistance enhanced superconformal filling 38 is enlarged to fill more of the volume of recess 4 from transition zones (32a, 32b) to distal position 14. With reference to panel E of FIG. 3, at time t4, for the subset that self-passivates, the deposition potential reverts to voltage V0 as the transition zones (32a, 32b) approaches close enough to field surfaces (10a, 10b) and away from distal position 14 that the suppressor concentration reaches the critical concentration CC associated with the supplied potential V0 and active deposition halts. Outside this subset, deposition continues, including over and onto the field surface (10a, 10b)). In either manner resistance enhanced superconformal filling 38 is formed to be disposed in recess 4 of substrate 2.

Metal can be deposited in various conventional ways that completely cover exposed surfaces of a material. Thin-film metallic microstructures have been produced by through-mask electroplating (also known as the LIGA). Through-mask deposition has been applied to a wide variety of metallic materials, including applications in both passive and active devices. LIGA combines template production (e.g., lithography) with electrodeposition whereby metal deposition proceeds on exposed surfaces of an underlying conductive seed layer. Additionally, damascene processes include metallizing a patterned dielectric with a thin seed layer across the entire surface followed by metal electrodeposition across the entire surface.

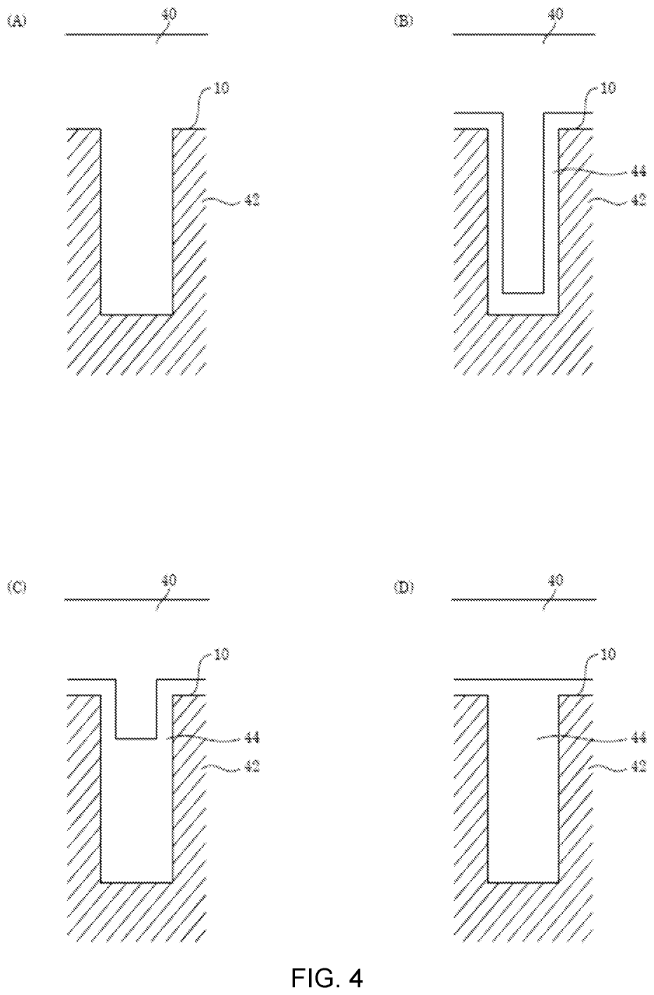

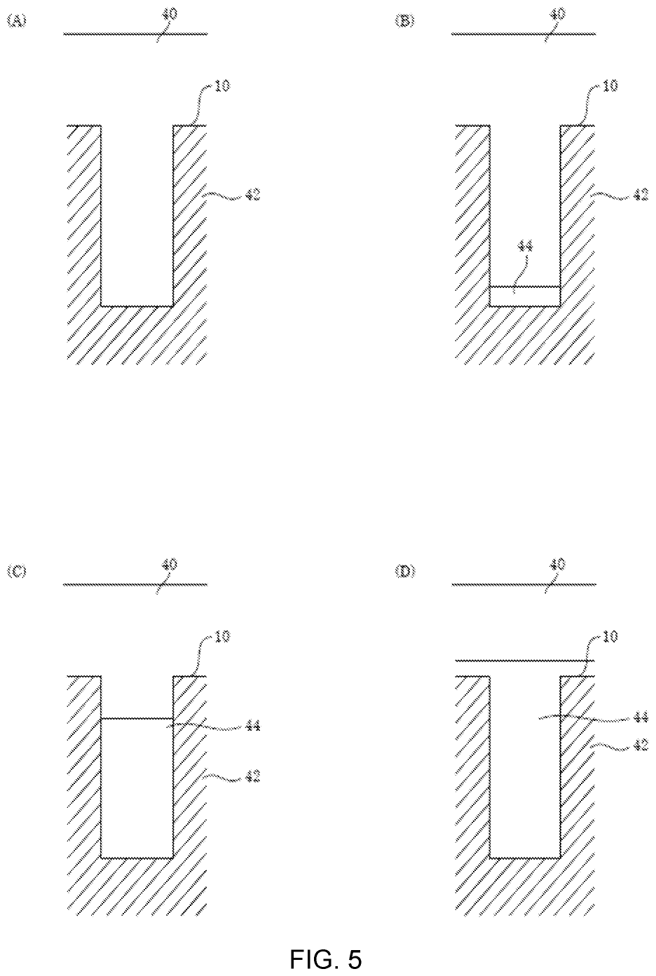

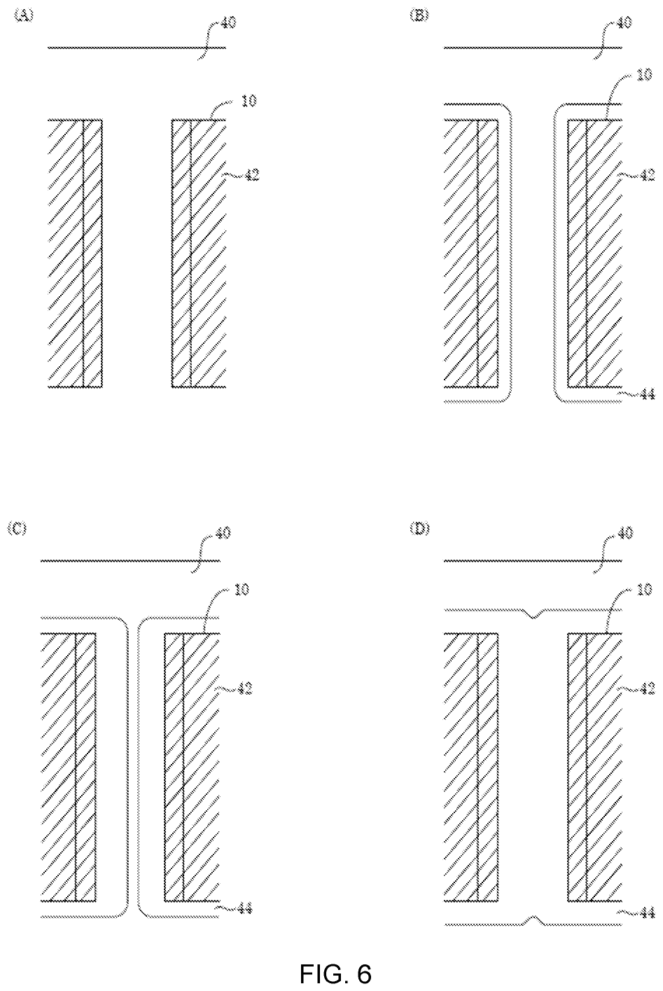

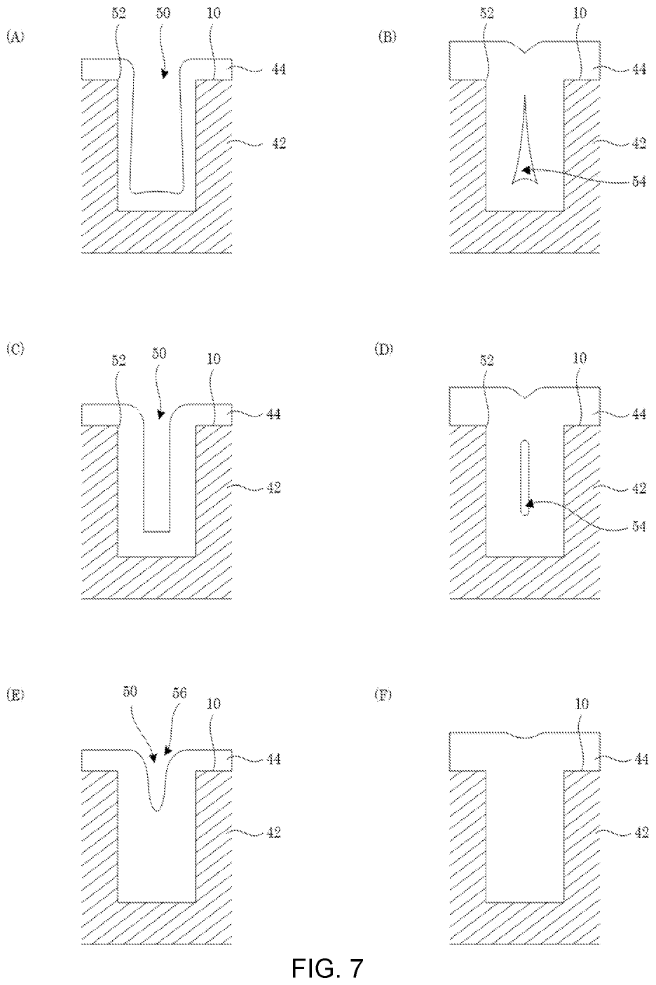

In this regard, with reference to FIG. 4, FIG. 5, FIG. 6, and FIG. 7, substrate 42 is exposed to the electrodeposition composition 40. As shown in FIG. 4, metal 44 is electrochemically deposited under essentially constant deposition potential on all exposed surfaces of substrate 42 including field 10. As shown in FIG. 5, metal 44 is electrochemically deposited under constant deposition potential at the bottom of substrate 42 and fills the feature from the bottom to the top of the feature and onto field 10 such that metal 44 is disposed on all exposed surfaces of substrate 42 including field 10. As shown in FIG. 6, metal 44 is electrochemically deposited under constant deposition potential on all exposed surfaces of substrate 42 including field 10.

FIG. 7 show comparative filling of trench or via 50 with metal 44 on substrate 42. Panel A of FIG. 7 shows comparative subconformal filling of metal 44 in trench or via 50 and planar region 10 of substrate 42. The subconformal filling of metal 44 has a greater deposition rate at pattern features such as at the top edges 52 of trench or via 50. The subconformal growth shown in panel A of FIG. 7 leads to void 54 as shown in panel B of FIG. 7. As electrodeposition of metal 44 continues, growth of metal 44 at top edge 52 continues until the metal 44 meets in a central location, forming and enclosing void 54 therein as shown in panel B of FIG. 7.

Panel C of FIG. 7 shows comparative conformal growth wherein metal 44 grows at a consistent rate on planar region 10 of substrate 42, within trench or via 50, and at top edges 52 of trench or via 50. Conformal growth as shown in panel C can form seam 54 as shown in panel D of FIG. 7. Seam 54 can be formed with continued growth of metal 44 inward from sidewalls of trench or via 50.

Panel E of FIG. 7 shows comparative superconformal filling wherein metal 44 forms a V-notch 56 centrally oriented within trench or via 50. Although conventionally referred to as bottom-up filling, a flat-bottomed geometry also occurring in a subset of cases, this comparative super conformal super filling produces a substantially uniform filling of trench or via 50 with metal 44 as shown in panel F of FIG. 7. Here, trench filling is characterized by uniform growth on field 10 and feature 50 as shown in panel B followed by development of V-notch 56 geometry with the deposition of metal 44 on field 10 as shown in panel E and panel F of FIG. 7.

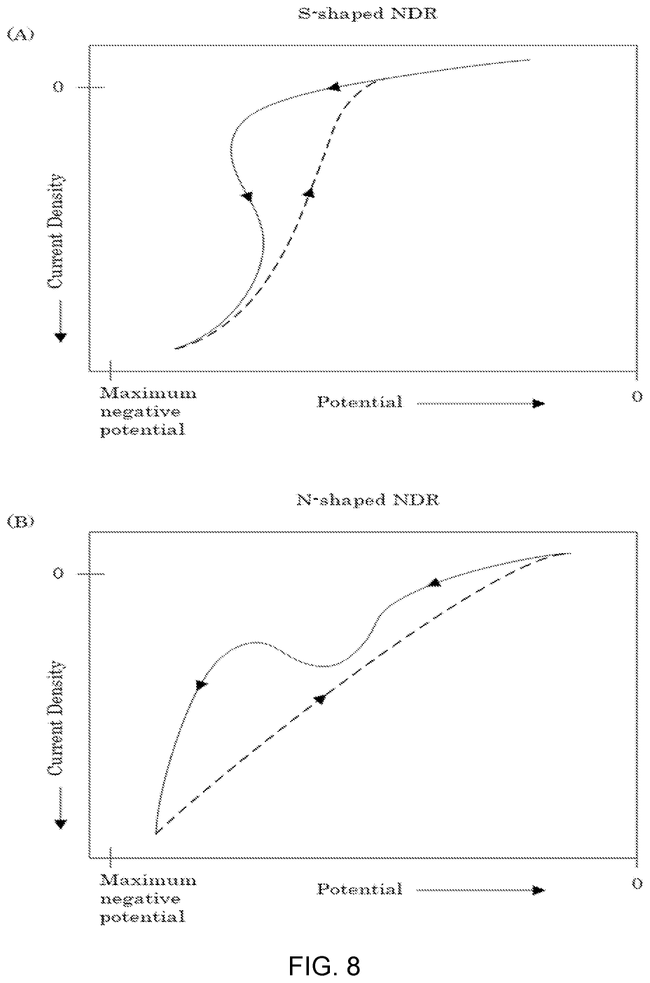

FIG. 8 panel A shows a cyclic voltammogram for an electrodeposition composition 30 that provides an S-shaped negative differential resistance (S-NDR) in cyclic voltammetry. FIG. 8 Panel B shows a cyclic voltammogram where some combination of metal ions, solvent, or additives provides a N-shaped NDR (N-NDR) in cyclic voltammetry. With S-NDR there is a potential range over which multiple deposition currents are permitted, two of which are stable and reflect a two-state active-passive system. The critical potential that marks the positive end of this potential range represents the point at which balance is first achieved between the rate of suppressor adsorption from the electrodeposition composition and the rate at which the adsorbed suppressor is consumed by the potential-dependent metal deposition. Active deposition at more negative potentials rapidly disrupts and buries the adsorbed suppressor while at more positive potentials deposition is effectively blocked by the suppressor-passivated surface. It is this combination that, coupled with suppressor diffusion, gives rise to the S-NDR voltammetric behavior.

It should be appreciated that, as described herein, a combination of the resistance member and hysteretic behavior of the cyclic voltammogram of the electrodeposition composition provide conditions for performing hysteretic current-voltage mediated void-free superconformal and bottom-up filling of recessed features of the substrate to form the resistance enhanced superconformal filling, e.g., with the system including a cell to hold the electrodeposition composition in communication with various electrodes and the substrate having recessed features.

The deposition potential existing on the substrate can be offset from the applied potential provided by the potentiostat by the resistive potential losses associated with the electrical current that is, itself, coupled with the metal deposition flowing through the resistive components of an electrodeposition system. The system resistance includes terms from the electrodeposition composition between the reference and substrate, an external resistance placed in electrical series between the potentiostat and the substrate, a resistive permeable or semipermeable baffle or membrane placed in the electrodeposition composition between the substrate and reference electrode, or a combination. If the system resistance is large enough the measured hysteretic current response to substrate potential is stretched to more negative applied potentials in plots versus applied potentials and the applied potential range of the S-NDR of the suppression breakdown in the plots is reduced. For large enough resistance the S-NDR current response can be hidden entirely in plots versus applied potential. That said, the hysteretic potential range associated with suppressor breakdown and the interface reaction on the substrate still remain in either case.

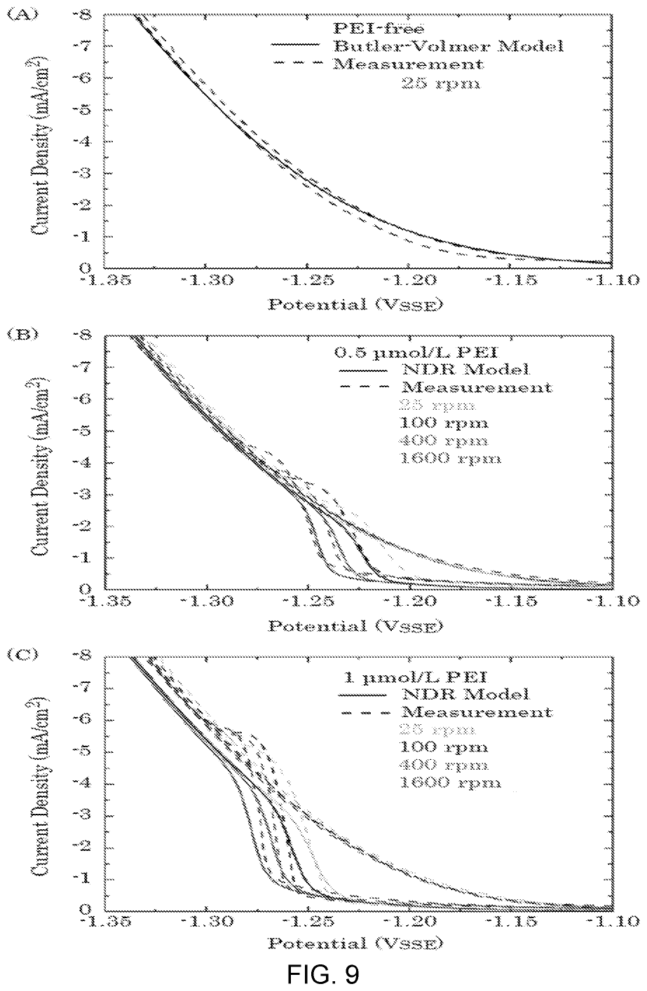

FIG. 9 Panel A shows cyclic voltammetry for Co deposition from a Co electrodeposition composition containing 1 mol/L CoSO₄+0.2 mol/L CoCl₂+0.5 mol/L HaBO₃, pH=3.5, Panel B shows results for the Co electrodeposition composition with addition of 0.5 μmol/L branched PEI (1800 g/mol) branched PEI additive and Panel C shows results for the Co electrodeposition composition with addition of 1 μmol/L branched PEI; cathodic currents are plotted positive and current densities were obtained from the measured current using the area of the rotating disk electrode (RDE). Resistive iR losses in the electrodeposition composition that are not corrected for, e.g., in data acquisition or plotting the data, broaden the S-shaped suppression breakdown so that S-NDR does not readily appear in plots of current density versus applied potential, but the hysteretic potential range for each condition appears in the plots. Simulations used to extract parameters for models are overlaid.

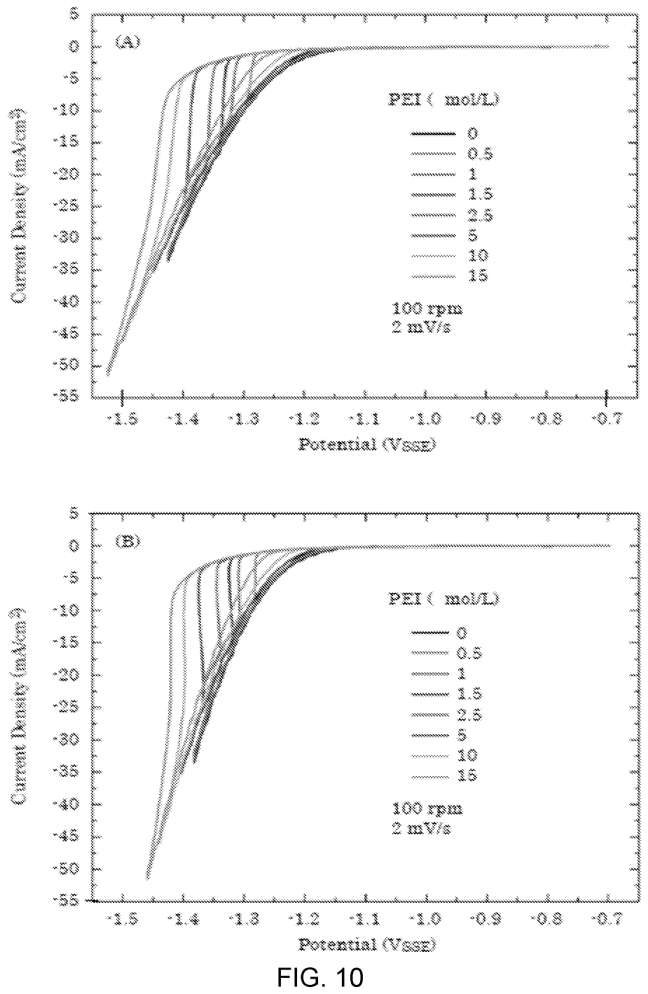

FIG. 10 Panel A shows cyclic voltammetry for Ni deposition from a nickel electrodeposition composition containing 40 mL of 1 mol/L NiSO₄+0.2 mol/L NiCl₂+0.5 mol/L H₃BO₃; cathodic currents are plotted positive. Voltammograms are also shown for electrodeposition composition that also contains branched PEI of the indicated concentrations to suppress the Ni deposition reaction. Inhibition of metal deposition is evident with even the lowest PEI additions. The suppression is followed at more negative potentials by sharp breakdown in the inhibition (suppression breakdown) after which the current merges with that for the additive-free case, the return scan yielding a hysteretic voltammogram. The cyclic voltammograms were collected with software compensating for roughly 80% of iR potential drop. FIG. 10 Panel B shows the same results after post experiment correction of the applied potential for the remaining 20% of iR potential drop to obtain the deposition potential on the substrate, which makes the S-NDR nature of suppression breakdown clearer and its potential range broader. Currents have been converted to current densities using the RDE area.

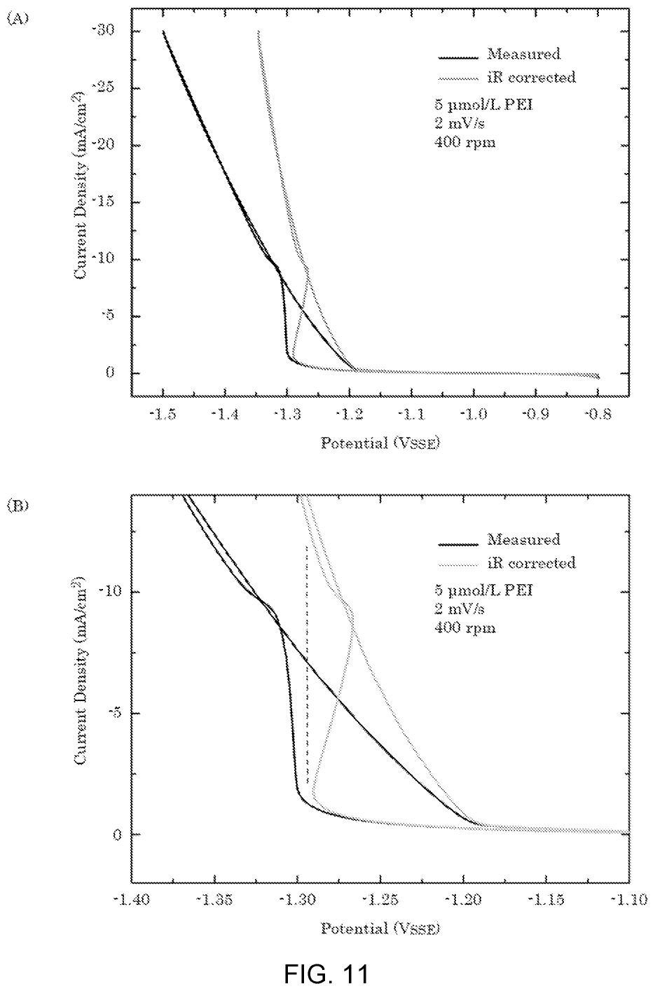

FIG. 11 Panel A shows cyclic voltammetry for Co deposition on an RDE in 1 mol/L CoSO₄+0.2 mol/L CoCl₂+0.5 mol/L HBO₃, pH=3.5, containing 5 μmol/L branched PEI (1800 g/mol) additive. The data, collected without compensation for the iR potential drop associated with the R≈9Ω cell resistance, is plotted against both the applied potential and the potential corrected for the iR potential drop. FIG. 11 Panel B shows the same data replotted to emphasize both the hysteretic potential range and S-shaped NDR that was lost in the data plotted against the applied potential (uncompensated) but appears in the data plotted against the substrate potential (fully compensated).

Coupling of suppression breakdown in the electrodeposition composition (also referred to herein as additive-containing electrolytes) that exhibit S-NDR in plots versus deposition potential and surface topography in filling of recessed features including through silicon via (TSV) can provide controlled superconformal or bottom-up filling.

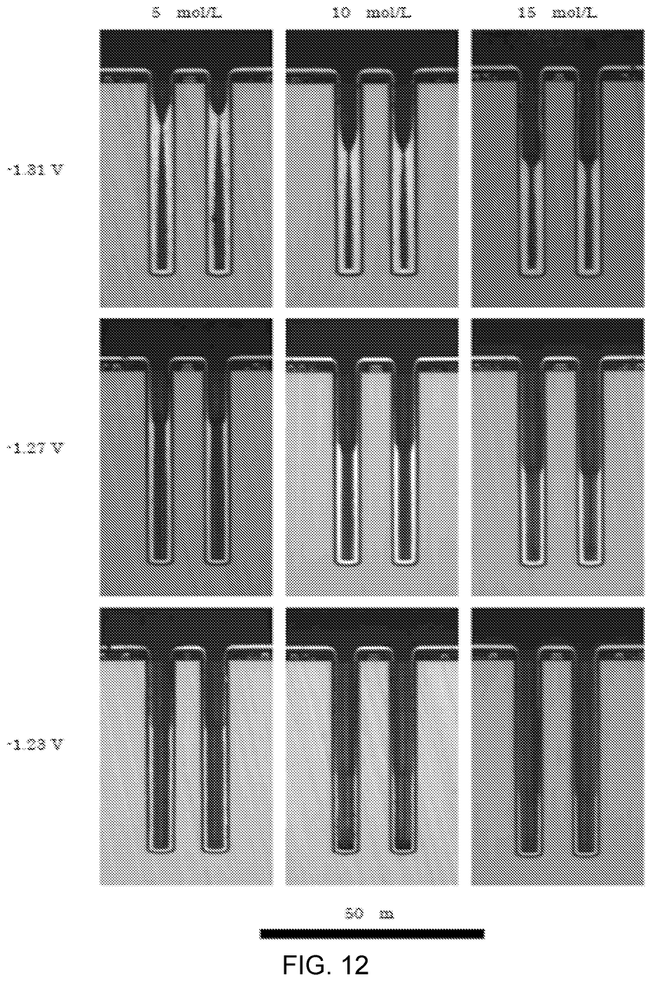

FIG. 12 shows Ni deposition from 1 mol/L NiSO₄+0.2 mol/L NiCl₂+0.5 mol/L HBO₃ electrodeposition composition of pH 3.1 plus PEI additive that exhibits S-NDR and its effect on the depth of suppression in recessed featured at three different applied potentials. Feature filling is shown in ≈56 μm deep TSVs of annular cross-section having a 1 μm thick Cu seed in the field and a lesser amount on the side walls. The depth of the transition where passive to active deposition occurs, and thereby the length of the suppressed region, increases with suppressor concentration. The effect of potential on the depth of the passive-active transition is also readily evident. Void formation is unavoidable for deposition starting at the more negative potential of −1.31 V that would otherwise permit filling to approach reasonably near the field surface, this being a case where passivation occurs where the suppressor concentration reaches CC for the applied potential.

For filling of a recess in this case, including a recessed through silicon via (TSV) geometry, the decrease of suppressor concentration moving from the field surface to the distal surface of a recess introduces a position-dependent shift of the critical potential associated with the bulk suppressor concentration in the electrodeposition composition toward more positive values compared to that of the free-surface. This accounts for passivation breakdown being localized within the feature where the height of the passive-to-active transition zone is determined by the transport constrained suppressor flux. The deposit in the actively plating region of the TSV reflects the active state of the bifurcated system.

The applied potential in this case thus determines the location where the electrode (or a surface of a recess) bifurcates into passive areas and regions of active metal deposition as well as how close active deposition may approach the surface field before self-passivation at a particular applied potential. Absent sufficient electrical resistance, a potentiodynamic stepped potential wave form or ramped potential waveform is required in many systems to progressively move the passive-active transition zone during metal deposition to both avoid void formation that occurs at more negative applied potentials and also enable filling sufficiently close to the field surface than is possible at more positive applied potentials. Higher suppressor concentrations, characterized by larger voltammetric hysteresis, provide a wider potential range that facilitates the use of such potentiodynamic control for superfilling recessed surface feature. Higher concentrations also enable use of the higher deposition rates at more negative potentials, permitting faster filling.

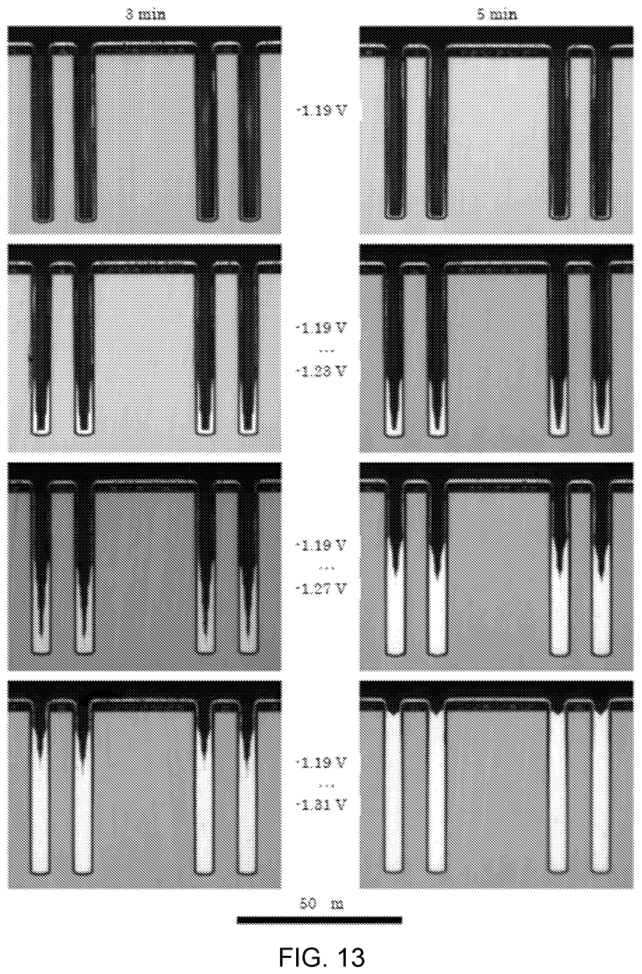

FIG. 13 shows experimental cobalt filling in annular TSVs after Co deposition in 1 mol/L CoSO₄+0.2 mol/L CoCl₂+0.5 mol/L H₃BO₃, pH=3.5, containing 20 μmol/L branched PEI (1800 g/mol) additive using such stepped potentiodynamic processes. Start and stop potentials are indicated, deposition starting at −1.19 V in all cases and proceeding in −20 mV increments to the indicated stop potential, all falling within the hysteretic potential range. The dwell time increment at each potential step is indicated. This is also a case where passivation occurs where the suppressor concentration reaches CC for the applied potential. The use of progressively wider ranges of the hysteretic potential range thereby enables progressively higher feature filling while longer deposition time at each potential allows more substantial filling of the volume within the active regions. Close inspection reveals inflection points along the v-notch growth surfaces that mark the heights of the passive-active transitions at the preceding, more positive potentials.

Processes using such stepped potentials to achieve void-free filling of recessed features can yield seam-free and void-free superconformal filling. However, they require significant experimental exploration to fix the significant number of free parameter in each process that include initial potential, final potential, potential step size and step durations in addition to electrodeposition composition and transport related parameters for each geometry of substrate and recessed feature.

Use of an appropriate system resistance permits the use of constant, or simplified potentiodynamic, applied potential that avoids both the pitfalls of filling only near the distal region that occurs at more positive applied potentials as well as voided filling that occurs at more negative applied potentials. The impact of system resistance can be inferred from deposition as applied potentials approach the positive end of the hysteretic range.

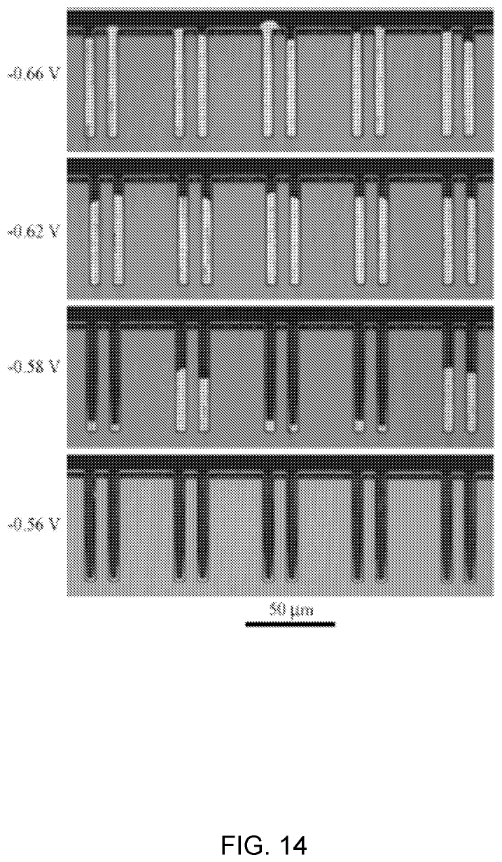

FIG. 14 shows cross-sectioned annular TSVs after 12 minutes of Cu deposition at the indicated potentials in 1 mol/L CuSO₄ and 0.5 mol/L H₂SO₄ electrodeposition composition containing 1 mmol/L NaCl and 12 μmol/L of a poloxamine additive (e.g., as commercially available under the tradename TETRONIC T701). Representative arrays of TSVs with 50 μm pitch. The images capture the consistency of filling observed at all potentials examined except −0.58 V. Suppression breakdown within the vias at this potential is seen to yield a bimodal distribution of filling heights. The patterned substrates were rotating at 100 rpm. Filling of only this fraction of the vias occurs because at this value of applied potential the iR drop associated with the system resistance for current from active deposition in more TSVs would push the substrate potential positive of the hysteretic potential range. This is not a case where passivation necessarily occurs where the suppressor concentration reaches CC for the applied potential, which is clear from an overfilling at the most negative potential of −0.66 V; it becomes so if the chloride concentration is decreased by an order of magnitude.

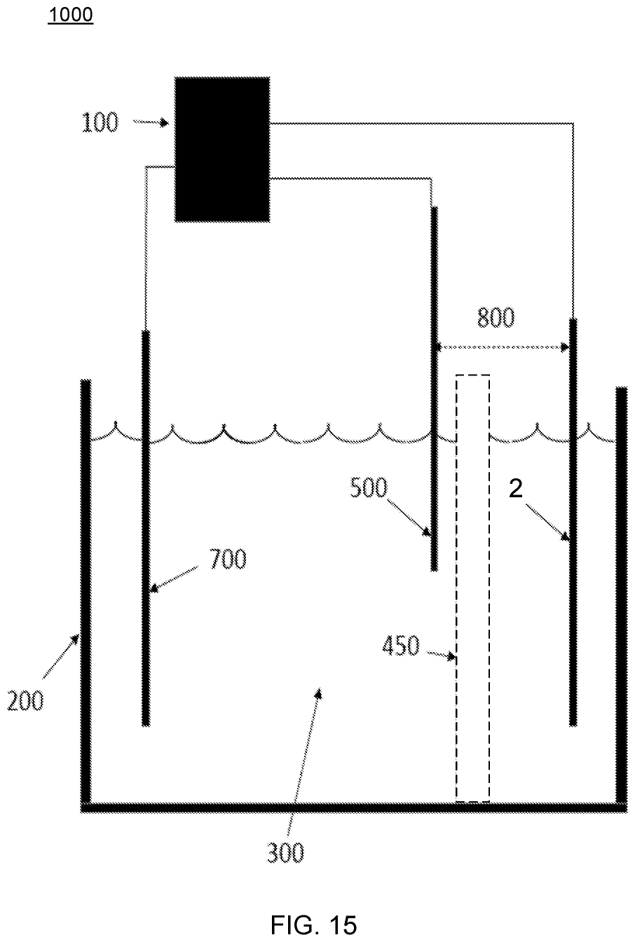

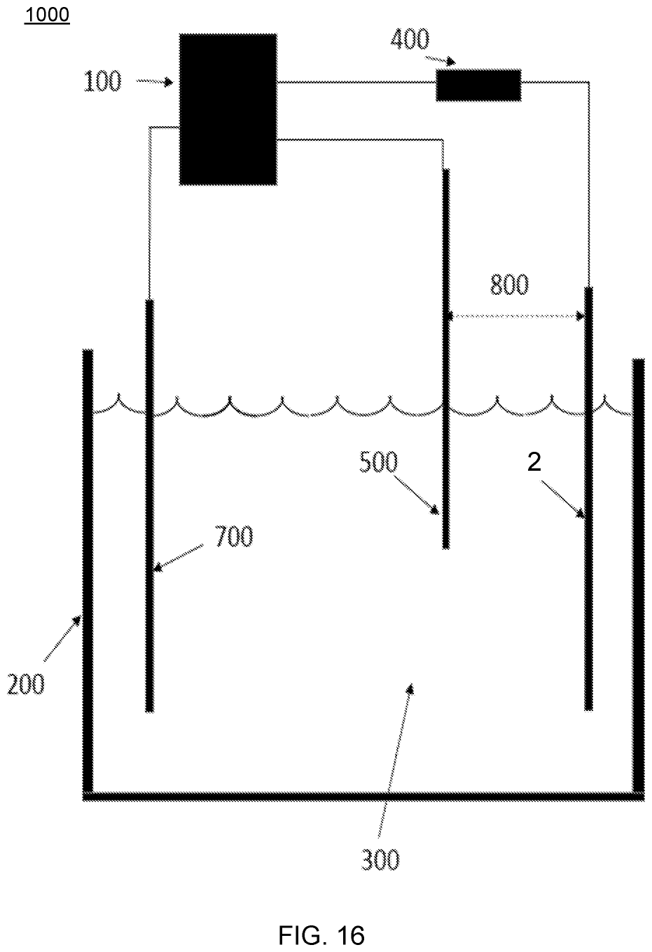

The process for performing hysteretic current-voltage mediated void-free superconformal and bottom-up filling of recessed features of a substrate with a resistance member can be performed in various environments such as system 1000. In an embodiment, with reference to FIG. 15 and FIG. 16, system 1000 includes: cell 200; electrodeposition composition 300 disposed in cell 200 and including: a metal electrolyte including a plurality of metal ions and a solvent; and a suppressor disposed in the solvent; and a hysteretic cyclic voltammogram; substrate 2 disposed in cell 200 in fluid communication with electrodeposition composition 300 and including: a field surface; and the recess disposed in the substrate, the recess including a distal position and a proximate position relative to the field surface of the substrate, such the recess is in contact with electrodeposition composition 300, such that an applied electric potential of the recess is under potentiostatically or potentiodynamically control with a potential wave form; the resistance member in communication with electrodeposition composition 300 and substrate 2, wherein system 1000 is arranged and configured such that the resistance member in presence of electrodeposition composition with the hysteretic cyclic voltammogram: autonomously reduces the deposition potential of the recess from that applied by the potential waveform, such that the recess is bifurcated into an active metal deposition region and a passive region in response to the deposition potential and ohmic variations of substrate 2; whereby, in response to bifurcating the recess, a transition zone is formed at an interface of the active metal deposition region and the passive region, such that the transition zone progressively moves closer to the field surface and away from the distal position through the metal deposition to reduce the metal ions and form metal to deposit the metal in the active metal deposition region and not in the passive region; thereby forming a resistance enhanced superconformal filling in the recess of substrate 2 from the metal in the active metal deposition region, wherein the resistance enhanced superconformal filling is void-free, disposed in the recess in the active metal deposition region from the distal position to the transition zone, and absent in the passive region between the proximate position and the transition zone, such that forming the resistance enhanced superconformal filling occurs in consequence of autonomously reducing the deposition potential of the recess with the resistance member in a presence of the hysteretic cyclic voltammogram of the electrodeposition composition.

In an embodiment, with reference to FIG. 15 and FIG. 16, the resistance member is selecting from the group consisting essentially of lumped resistor 400, baffle 450, and a selected interelectrode separation distance 800 between substrate 2 and reference electrode 500 in electrical communication with electrodeposition composition 300. In an embodiment, with reference to FIG. 16, the resistance member is lumped resistor 400, and lumped resistor 400 includes a resistor in electrical communication with and electrically interposed between substrate 2 and counter electrode 700 in electrical communication with electrodeposition composition 300. In an embodiment, the resistance member is baffle 450, and baffle 450 is in fluid communication with and fluidically interposed between substrate 2 and reference electrode 500. In an embodiment, the resistance member is selected interelectrode separation distance 800 between substrate 2 and reference electrode 500 in electrical communication with electrodeposition composition 300, and the process can include adjusting interelectrode separation 800.

FIG. 15 shows system 1000 that includes electrodeposition cell 200, potentiostat 100 that supplies the applied potential to a working electrode substrate 2, counter electrode 700, reference electrode 500, substrate 2, and baffle 450 (e.g., a permeable or semipermeable resistive element or membrane) disposed in electrodeposition composition 300 disposed in cell 200. Interelectrode separation 800 is a distance between the reference electrode 800 and substrate 2. Interelectrode separation 800 provide resistance to system 1000 that includes contributions to electrical resistance experienced by current flowing from the potentiostat 100 connection to substrate 2 and to a sampling distance of the reference electrode 800 due to a passage of a current associated with deposition on the substrate through the electrodeposition composition 300. A selected system resistance is provided baffle 450. It should be appreciated that baffle 450 can be arranged to not interfere with kinetic factors related to transport for forming the resistance enhanced superconformal filling in the recessed features of substrate 2.

FIG. 16 shows system 1000 that includes electrodeposition cell 200, potentiostat 100 that provides the applied potential through lumped resistor (e.g., an external resistor) 400, counter electrode 700, reference electrode 500, and substrate 2 disposed in electrodeposition composition 300 disposed in cell 200. Interelectrode separation 800 between reference electrode 500 and substrate 2 impacts resistance of system 1000, e.g., between power supply 100 connection to substrate 2 and connection of power supply 100 to reference electrode 500 due to passage of current associated with deposition of metal in recess features of substrate 2 through electrodeposition composition 300. System resistance can be selectively obtained by lumped resistor 400.

Elements of system 1000 can be various sizes. It is contemplated that elements can be selected based on desired operating parameters. Such elements can be made of a material that is physically or chemically resilient in an environment in which system 1000 is operated. Exemplary materials include a metal, ceramic, thermoplastic, glass, semiconductor, and the like. Certain elements of system 1000 can be made of the same or different material and can be monolithic in a single physical body or can be separate members that are physically joined.

Substrate 2 can be electrically conductive, electrically semiconductive, or electrically insulating. It is contemplated that substrate 2 can have a gradient in electrical conductivity Exemplary electrically conductive substrates 2 include copper, gold, nickel, cobalt and the like. In an embodiment, substrate 2 is electrically conductive copper. Exemplary electrically semiconductive substrates 2 include silicon, germanium, gallium nitride, zinc oxide and the like. In an embodiment, substrate 2 is electrically semiconductive such as silicon. In certain configurations, e.g., a back contact geometry, the resistance of the semiconductor can be an external resistance. Exemplary electrically insulating substrates 2 include glass, quartz, and the like. In an embodiment, substrate 2 is electrically insulating such as glass. Substrate 2 can be any shape or size that does not interfere with formation of resistance enhanced superconformal filling 38 in recess. Moreover, substrate 2 can be an element of a larger structure such as a computer chip, interposer, circuit board, and the like. Substrate 2 can be a same or different material as the larger structure. Field surface 10 a substrate 2 can be planar, curved, irregular, corrugated, and the like, or a combination thereof.

Recess 4 (also referred to herein as recessed feature) is disposed on substrate 2 and receives electrodeposition composition 30 for formation of resistance enhanced superconformal filling 38 therein. Recess 4 can have a low aspect ratio or high aspect ratio. As used herein, “aspect ratio” refers to a ratio of length L to width W of recess 4. The aspect ratio can be from 0.5 to 200, specifically from 0.5 to 50, and more specifically from 0.5 to 10. It is contemplated that length L can be from 5 nanometers (nm) to 1000 micrometers (μm), specifically from 5 nm to 100 μm, and more specifically from 10 nm to 10 μm. Width W can be from 5 nanometers (nm) to 400 micrometers (μm), specifically from 5 nm to 100 μm, and more specifically from 10 nm to 10 μm. In an embodiment, recess 4 has a depth from the field surface to the distal position that is from 10 nm to 900 μm, and an aspect ratio from 1 to 70. It is contemplated that the recess can include a through hole, a blind hole, or a combination comprising at least one of the foregoing recesses.

A shape of recess 4 can be any shape and can include a dendritic arm that extends into substrate 2. Wall 6 and terminal wall that borders recess 4 independently can be curved, linear, irregular, or a combination thereof. Further, recess 4 can be a through hole or blind hole. Recess 4 includes a pinhole, aperture, capillary, fracture, seam, trench and the like.

It is contemplated that substrate 2 can include body member 16, electrically conductive layer 18 that is recessed with respect to field surface 10, and recess 4 bounded by wall 6 and terminal wall 8. Here, electrically conductive layer 18 provides an electrically conductive surface that can be subjected to a deposition potential for reducing metal ions in electrodeposition composition to form resistance enhanced superconformal filling 38 in recess 4. Exemplary materials for electrically conductive layer 18 include copper, gold, and the like. In an embodiment, electrically conductive layer 18 includes copper. Electrically conductive layer 18 can have a thickness selected to support electrodeposition of the metal and can be from 5 nanometers (nm) to 10 micrometers (μm), specifically from 5 nm to 10 μm, and more specifically from 5 nm to 1 μm.

To form resistance enhanced superconformal filling 38 in recess 4, metal ions in electrodeposition composition 30 are reduced at wall 6, terminal wall 8, or combination thereof. Electrodeposition composition 30 can be a fluid such as a gas or liquid. In an embodiment, electrodeposition composition 30 is the liquid and includes metal ions and a suppressor disposed in the solvent.

Electrodeposition composition 30 also can include additional additives such as an accelerator, leveler, source of halide ions, grain refiner, defoaming agent, alloying metal and the like. Exemplary levelers include an amine, a polyethyleneimine, a phenolphthalein, or alkylammonium cations, or a combination comprising at least one of the foregoing levelers.

The metal ions include ions of nickel (Ni²⁺), ions of cobalt (Co²⁺), gold (Au⁺ and Au³⁺), copper (Cu²⁺ or Cu⁺), iron (Fe²⁺ or Fe³⁺), platinum (Pt⁴ or Pt²⁺) and iridium (Ir³⁺ or Ir⁴⁺), rhodium Rh³⁺, palladium Pd²⁺, cobalt Co²⁺, zinc Zn²⁺, bismuth Bi³⁺, lead Pb²⁺, rhenium Re⁷⁺, silver Ag⁺, tin Sn²⁺, tungsten W⁶⁺, molybdenum Mo⁶⁺ or a combination thereof. The source of metal ions can be a metal salt such as a nickel salt, cobalt salt, gold salt, and the like. The metal salt that is soluble in electrodeposition composition 30 can be used.

In an embodiment, the metal ions include Fe²⁺, Fe³⁺, Pt²⁺, Pt⁴⁺, Ir³⁺, Ir⁴⁺, Rh³⁺, Pd²⁺, Co²⁺, Ni²⁺, Au³⁺, Zn²⁺, Bi³⁺, Pb²⁺, Re⁷⁺, Au⁺, Ag⁺, Sn²⁺, W⁶⁺, Mo⁶⁺, Cu²⁺, Cu⁺, or a combination comprising at least one of the foregoing metal ions, and the metal includes cobalt, gold, nickel, iron, silver, platinum, iridium, copper or a combination comprising at least one of the foregoing metals.

A copper salt can be used as a source of copper ions. Exemplary copper salts include copper sulfate, copper sulfonate, copper acetate, copper gluconate, copper fluoroborate, copper halides, copper nitrate, copper alkanesulfonates, copper arylsulfonates, copper complexes of citrate, tartrate ethylenediamine, ethylenediaminetetraacetic acid and the like. Suitable copper alkanesulfonates include copper methane sulfonate, copper ethanesulfonate, and copper propanesulfonate. Suitable copper arylsulfonates include copper benzenesulfonate, copper toluenesulfonate, and copper phenolsulfonate. The copper salt can be present in electrodeposition composition 30 in an amount sufficient to provide an amount of copper ion from 0.1 grams per liter (g/L) to 180 g/L, specifically from 1 g/L to 50 g/L, and more specifically from 1 g/L to 10 g/L.

A nickel salt can be used as a source of nickel ions. Exemplary nickel salts include nickel sulfate, nickel sulfonate, nickel acetate, nickel gluconate, nickel fluoroborate, nickel halides, nickel nitrate, nickel alkanesulfonates, nickel arylsulfonates, complexes of citrate, tartrate ethylenediamine (en), ethylenediaminetetraacetic acid (edta) and the like. Suitable nickel alkanesulfonates include nickel methane sulfonate, nickel ethanesulfonate, and nickel propanesulfonate. Suitable nickel arylsulfonates include nickel benzenesulfonate, nickel toluenesulfonate, and nickel phenolsulfonate. The nickel salt can be present in electrodeposition composition 30 in an amount sufficient to provide an amount of nickel ion from 0.1 grams per liter (g/L) to 180 g/L, specifically from 1 g/L to 50 g/L, and more specifically from 1 g/L to 10 g/L.

A cobalt salt can be used as a source of cobalt ions. Exemplary cobalt salts include cobalt sulfate, cobalt sulfonate, cobalt acetate, cobalt gluconate, cobalt fluoroborate, cobalt halides, cobalt nitrate, cobalt alkanesulfonates, cobalt arylsulfonates, complexes of citrate, tartrate ethylenediamine, ethylenediaminetetraacetic acid and the like. Suitable cobalt alkanesulfonates include cobalt methane sulfonate, cobalt ethanesulfonate, and cobalt propanesulfonate. Suitable cobalt arylsulfonates include cobalt benzenesulfonate, cobalt toluenesulfonate, and cobalt phenolsulfonate. The cobalt salt can be present in electrodeposition composition 30 in an amount sufficient to provide an amount of cobalt ion from 0.1 grams per liter (g/L) to 180 g/L, specifically from 1 g/L to 50 g/L, and more specifically from 1 g/L to 10 g/L.

A gold salt can be used as a source of gold ions. Exemplary gold salts include gold sulfate, gold sulfonate, gold acetate, gold gluconate, gold fluoroborate, gold halides, gold sulfite, gold nitrate, gold alkanesulfonates, gold arylsulfonates, and the like. Suitable gold alkanesulfonates include gold methane sulfonate, gold ethanesulfonate, and gold propanesulfonate. Suitable gold arylsulfonates include gold benzenesulfonate, gold toluenesulfonate, and gold phenolsulfonate. The gold salt can be present in electrodeposition composition 30 in an amount sufficient to provide an amount of gold ion from 0.1 grams per liter (g/L) to 180 g/L, specifically from 1 g/L to 50 g/L, and more specifically from 1 g/L to 10 g/L.

The electrodeposition composition can include anions for the metal ions. Exemplary anions include sulfate, chloride, sulfite, perchlorate, bromide, citrate, tartrate, ethylenediamine, ethylenediaminetetracetic acid, or a combination comprising at least one of the foregoing anions. It is contemplated that the electrodeposition composition can include chloride, bromide, or iodide.

The metal electrolyte can be alkaline or acidic. An acid that is compatible with the source of metal ions can be present in electrodeposition composition 30. Exemplary acids include sulfuric acid; acetic acid; fluoroboric acid; nitric acid; sulfamic acid; phosphoric acid; hydrogen halide acids such as hydrochloric acid; alkanesulfonic acids and arylsulfonic acids such as methanesulfonic acid, ethanesulfonic acid, propanesulfonic acid, toluenesulfonic acid, phenolsulfonic acid and benzenesulfonic acid; halogenated acids such as trifluoromethylsulfonic acid and haloacetic acids such as trifluoroacetic acid: and the like; or combination thereof. The metal electrolyte is present in an amount sufficient to provide electrical conductivity to electrodeposition composition 30. A pH of the acidic electrolyte can have a value of less than 7, and specifically less than 2. Exemplary alkaline electrodeposition compositions can use pyrophosphate, en, EDTA, or carboxylic acids in the metal electrolyte although other electrolytes can be present. It should be appreciated that the pH of the metal electrolyte can be adjusted. The acid or alkaline additive species can be present in electrodeposition composition 30 in an amount from 0 to 200 g/L, specifically from 5 to 200 g/L. and more specifically from 0 to 120 g/L.

Exemplary solvents for electrodeposition composition 30 include water, an alcohol, polar organic solvent, and the like, deep eutectic solvents based on choline chloride, room temperature ionic liquids or a combination thereof. The solvent can be present in a wide range of amounts.

As used herein, “suppressor” refers to an additive that suppresses a rate of electrodeposition of the metal as resistance enhanced superconformal filling 38. In electrodeposition composition 30, the suppressor decreases the rate of electrodeposition of the metal. Exemplary suppressors include a polyethylene oxide; a polyethylene glycol, alkylammonium cations, polyethers, poloxamers, polyoxamines, optionally in conjunction with halides, polyethyleneimine, nitrogen bearing polymers, PVP, polypyrrole, pyridine, and alkylammonium salts, benzotriazole, benzimidazole, mercapto-benzimidazole, and other N- and/or S-bearing aromatics, or a combination thereof. The polyethyleneimine can have a repeating unit formula (1).

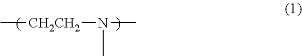

The polyethyleneimine compound can include from 1 to _2, 4 or more, or 6 or more, of the repeating unit of formula 1. The polyethyleneimine can include nitrogen atoms that are present as a primary amine, secondary amine, or tertiary amine and can include a terminal hydroxyl group, e.g., as a polyhydroxylamine. The polyhydroxylamine can have a structure of formula (2): R″HN—(CH₂—CH₂—NR)ₐ—R′, wherein R is a group including the repeating units of formula (1); R′ and R″ independently are each a hydrogen atom or hydroxyl group, and a is an integer of 4 or greater.

The polyethyleneimine can have a linear structure in which the repeating units of formula (1) are linearly linked or a molecule in which such repeating units are linked in a branched structure. Examples of polyethyleneimine compounds that exhibit linear or branched structures are provided as formulas (3) and (4).

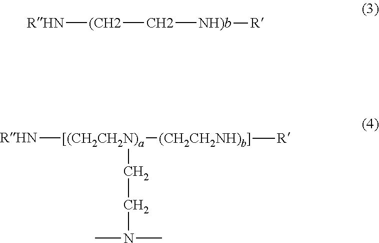

wherein R′ and R″ are as described above, and a and b are integers of 4 or greater, specifically 6 or greater. In formula (4), linkage groups of the nitrogen atom are not shown, but the linkage groups can be selected from repeating units of formula (1), hydrogen atoms and hydroxyl groups. In formula (4), repeating units having branches and repeating units not having branches can be linked randomly as desired.

When the polyethyleneimine compounds have a branched structure, branching chains (represented by R in formula (2)) having any length and branching form are bonded to the nitrogen atom in any number of repeating units and at any position from the termini of the side chains in the polyethyleneimine to which multiple units of the aforementioned repeating unit (1) are linked. With regard to bonding format in the branched regions, the bondable carbon atoms in repeating units (1) (carbon atoms that are not bonded to nitrogen atoms in the above repeating units) are bonded to the nitrogen atoms of other repeating units (nitrogen atoms to which R is bonded in formula (2)). Branching chains in the polyethyleneimine (represented by R in formula (2)) also can be chains that have the repeating units of formula (1), or can be chains formed by the linkage of any number of repeating units, where the linkage mode can manifest a branching or linear structure.

In formula (2), R′ and R″ are each independently hydrogen atoms or hydroxyl groups such that the terminals of the polyethyleneimine will be amino groups or hydroxyamino groups. In addition, the aforementioned branched chains in the polyethyleneimine can be amino groups or hydroxyamino groups.

A molecular weight of the polyethyleneimine can be, e.g., 300-100,000, with 1000-20,000 being preferred. The polyethyleneimine can be present in electrodeposition composition 30 in an amount from 0.01 g/L to 100 g/L, specifically from 0.01 g/L to 100 g/L, and more specifically from 0.01 g/L to 100 g/L.

Similarly, polyethers or block co-polymers such PEO-PPG-PEO or PPO-PEO-PPO, poloxamers, or poloxamines can be used. Exemplary amount of each independently can be from 0.1 μmol/L to 500 μmol/L.

Accordingly, the resistance member in presence of the electrodeposition composition in contact with substrate 2 can make the resistance enhanced superconformal filling due to autonomously reducing the deposition potential of the recess. The potential wave form used in the process for filling the recessed features of the substrate can include a single fixed applied potential. It is contemplated that deposition can be controlled by an applied potential imposed in a two or three electrode configuration (e.g., as shown in FIG. 15 and FIG. 16) by an external power supply or potentiostat. In addition to autonomous modulation of substrate potential by ohmic losses associated with the resistance member, the applied potential can be modulated in steps or ramped to fill different shapes or sizes of recessed features.

It should be appreciated that various resistance members can be used, including the lumped resistor in an electrical circuit electrically interposed between and in electrical communication with the reference electrode and the substrate and can be an input to the potentiostat that provides the applied potential. Reducing the deposition potential of the recess from that applied by the potential waveform due to ohmic resistance can occur with current flow through a permeable or semipermeable baffle disposed in the electrodeposition composition and interposed between the reference electrode and the substrate. Optionally, the interelectrode separation can be changed between the working electrode substrate and the reference electrode. A magnitude of resistance provided by the resistance member can be from 1 times to 1000 times greater than the system resistance from closely disposing the reference electrode to the substrate, such as a separation of about 1 mm to 10 mm, e.g., 2.5 mm. It is contemplated that an uncompensated ohmic drop for conductivity of the electrodeposition composition and a geometric configuration of the cell, with the working and counter electrode positioned at opposite end of circular tube of radius R_{c}, has ohmic losses due to current flow in the electrodeposition composition given by

$${Ω}_{s} = \frac{L}{π {R}_{c}^{2} κ} \qquad [ 1 ]$$

For a given substrate, area is the cross sections of the cell (e.g., πR_{c}²) so that changes in Ωs are accomplished by adjusting the position of the RE/CE, L, or through the solution conductivity, κ.

In an embodiment, substrate 2 includes recess 4 Recess 4 can be formed in substrate 2 by lithographic patterning, etching, laser drilling, cutting, scratching, mechanical deformation, thermal cycling and the like, or a combination thereof.

It is contemplated that substrate 2 can be exposed to electrodeposition composition 30, e.g., by immersing, coating, spraying, and the like substrate 2 with electrodeposition composition 30. Electrodeposition composition 30 can be prepared by dissolving salts in solvent sequentially or in combination or mixing in pre-dissolved salts. Exposing recess 4 to electrodeposition composition 30 can be accomplished by partial immersion or total immersion of a substrate within a container already containing electrodeposition composition or addition of electrodeposition composition to a container already containing the substrate or the like.

Potentiostatically or potentiodynamically controlling the deposition potential of the recess with a potential wave form can be performed by a potentiostat connected through a resistor to the substrate or with a resistive baffle or membrane placed in the electrodeposition composition between the substrate and reference potential or by controlling the resistivity of the electrodeposition composition and the distance between the reference electrode and the substrate or a combination thereof. A potential waveform can include a single potential, potential step waveform, potential ramp, or a combination thereof.

Formation of potential controlled superconformal filling 38 from transition zone 32 to distal position 14 in active metal deposition region 36 while formation of potential controlled superconformal filling 38 is absent in passive region 34 occurs due to electrodeposition composition 30 in combination with time-dependent potential drop across a resistance between the potentiostat supplying power and the substrate that reduces the deposition potential at wall 6 of recess 4 from the potential supplied by the potentiostat. In an embodiment, electrodeposition composition 30 provides an S-NDR cyclic voltammogram, e.g., as shown in panel A of FIG. 8. Some combination of metal ions, solvent, or additives provide a N-shaped NDR (N-NDR) as shown in panel B of FIG. 8. The S-NDR and potentiodynamically control of the deposition potential above suppression breakdown voltage VB provide selected electrodeposition of resistance enhanced superconformal filling 38 in recess 4 with an absence of resistance enhanced superconformal filling 38 on field surface 10 of substrate 2.

The process for forming resistance enhanced superconformal filling 38 has numerous beneficial uses, including simplified control and a wider potential range for void-free and defect-free metal deposition in recesses that can include different feature shapes, feature widths and feature depths on a single substrate. In an embodiment, resistance enhanced superconformal filling 38 can be used to copper fill through vias with different dimensions on a glass interposer. In another embodiment, resistance enhanced superconformal filling 38 can be used to copper fill through silicon vias with different dimensions.

Advantageously, the resistance member enables the beneficial behavior of S-NDR for the electrodeposition composition under a fixed applied potential to be attenuated for uniform and complete filling for an array of features with spontaneous self-termination upon completion of the filling process by formation of the resistance enhanced superconformal filling. Moreover, the process for performing hysteretic current-voltage mediated void-free superconformal and bottom-up filling of recessed features of a substrate with a resistance member overcomes limitations and disadvantages of conventional processes that typically involve galvanostatic control, optimization, and monitoring of the charge during deposition. The process for performing hysteretic current-voltage mediated void-free superconformal and bottom-up filling of recessed features of a substrate with a resistance member provides more complete void-free feature filling followed by self-termination upon making the resistance enhanced superconformal filling compared with conventional processes.

The articles and processes herein are illustrated further by the following Example, which is non-limiting.

### Example

### Effect of Control Mode and Uncompensated Resistance in S-NDR Systems

Void-free Cu electrodeposition in high aspect ratio features relies on preferential growth proceeding from the most recessed surfaces where sustained breakdown of the co-adsorbed polyether-halide suppressor layer occurs. Localization is the result of positive feedback between inhibitor breakdown and metal deposition subject to transport limitations on the suppressor precursor(s). This gives rise to a negative differential resistance (S-NDR) that, convolved with ohmic resistance of the system that has not been compensated for by software or hardware (uncompensated), results in electrode bifurcation into active and passive zones. The interplay between the additive derived S-NDR behavior, uncompensated system resistance, and potentiostatic regulation is explored in comparison to galvanostatic feature filling. Uncompensated resistance arises from the working electrode contact and electrolyte between the working and reference electrode. For a CuSO₄—H₂SO₄ electrolyte containing 80 μmol/L Cl⁻ and 40 μmol/L polyether, simulations of potentiostatic deposition with minimal uncompensated resistance reveal a narrow window between fully passive and voided feature filling; bottom-up filling even terminates prematurely under the most favorable conditions. In contrast, optimized galvanostatic operation enables void-free feature filling with termination dictated by the operator. Increasing the uncompensated resistance along with application of accordingly more negative applied potentials produces filling dynamics that blends the positive attributes of galvanostatic and potentiostatic deposition to enable complete, void-free feature filling with spontaneous passivation near the feature opening. Importantly, these beneficial filling effects are also evident for via and trench arrays with variable widths or heights.

Electrochemical deposition is widely used to fabricate microscale structures ranging from nanometer sized on-chip interconnects to larger scale wiring in printed circuit boards and packaging for microelectromechanical devices. Central to these applications is the need to fill high-aspect ratio recessed surface features. Multicomponent additive packages are involved for void-free filling of sub-micrometer trenches and vias. In the case of Cu electrodeposition, three components are often used that include a polyether-based suppressor, sulfonate-terminated thiol or disulfide accelerator, and some N-bearing leveler molecules, all of which have distinctive effects on the rate of metal deposition. Superconformal feature filling results from competitive adsorption between these species that, in the case of sub-micrometer features, includes the effect of rapid area change on the coverage of the respective species. For larger scale features constraints on mass and charge transport become increasingly important to the filling process. Herein the filling of larger features, such as through silicon vias (TSV) whose depth approaches the thickness of the adjacent hydrodynamic mass transport boundary layer, are examined. For these conditions a more extreme form of preferential bottom-up feature filling is possible based on selective breakdown of passivating additives that otherwise serve to block access of the metal cations to the electrode surface.

In the case of Ni, Co, and Au, a single suppressing additive is used to induce localized deposition while suppression of Cu deposition involves co-adsorption of a polyether and halide. Polarization to sufficiently negative potentials disrupts the adlayer, permitting Cu²⁺ access to the electrode for electrodeposition. In addition to applied potential, suppressor breakdown depends on the concentrations of its precursor components and hydrodynamics. Activation involves suppressor desorption and/or incorporation of some components into the growing deposit. It is also possible that the desorption process itself may be further stimulated by metal deposition. In either case, the positive feedback associated with potential-driven activation results in a sharp increase in deposition current and thereby significant hysteresis in cyclic voltammetry and galvanodynamic measurements. Operating at applied potentials within the hysteretic region leads to bifurcation of the electrode surface into active and passive reaction zones that give rise to Turing patterns on planar electrodes and bottom-up filling of recessed electrode geometries such as through-holes and TSVs. The two phenomena are closely connected, resulting from differing time-scales between the ‘fast’ electronic response and ‘slow’ evolution of chemical gradients. The topography of the TSV substrate is coupled with local mass transport conditions that serve to guide the electrode bifurcation, where the planar field is passive due to a higher suppressor flux and active metal deposition occurs on the most recessed surfaces. A contribution to the phase separation process is the longer range global coupling associated with the electrical response that is much faster than the development of suppressor and metal cation gradients driven by diffusion, electromigration, and sometimes convection. Dynamic coupling between these two effects underlies patterning associated with S-NDR systems. The strength of global coupling is a function of both the magnitude and geometry of the uncompensated resistance in the system. In a related fashion, the interaction between critical bistable systems and different regulation modes, controlled potential versus current, have been examined with particular attention to the important role of uncompensated resistance.

Uncompensated resistance includes ohmic losses associated with current flow in the electrolyte as well as external losses associated with the working electrode substrate contacts that in combination cause the overpotential at the working electrode to deviate from the applied potential. These respective resistances are design parameters that include variation of the reference electrode position in 3-electrode systems, introduction of a porous, resistive baffle into the electrolyte between the reference and working electrode, and the insertion of an external resistor between the working electrode and the sensing point in the potentiostatic circuit.

In the case of a 2-electrode cell operating under constant applied potential, i.e. with the reference and counter electrode shunted, an external in-line resistor can be introduced. However, knowledge of the counter electrode reaction characteristics is required for analysis of the working electrode overpotential. With the development of a suitable counter electrode it is interesting to contemplate the use of a 2-electrode cell run under constant applied potential as a useful variant to conventional galvanostatic operation. If the shunted counter/reference electrode reaction is non-polarizable and the symmetry of the cell and workpiece are uniform, so that the lumped resistor approximations for the electrolyte can be used, then modeling of the 2- and 3-electrode configurations are analogous to one another. That said in moving beyond 1-D models, the location of the reference electrode, i.e., Haber-Luggin capillary, with respect to a multidimensional working electrode can be destabilizing to a uniform electrode state and the effect is accentuated as the reference point is brought closer to the working electrode.

In 2-D simulations this concern is mitigated by sampling the reference potential at a plane within an idealized parallel plate cell where the potential is expected to be uniform based on the primary current distribution and the periodic nature and scale of the workpiece patterns.

Post-measurement correction for the uncompensated ohmic losses in conventional voltammetry reveals an inversion, or bi-stable S-shaped negative differential resistance (i.e., a decrease in driving force associated with an increase in reaction rate) that underlies the behavior of the suppressor based critical system. In the absence of ohmic losses, potentiostatic control within the S-NDR region is not viable as the system is unstable and jumps to either the active or passive branch. Rather, the presence of a significant uncompensated resistance enables operation within the hidden S-NDR region by providing a single valued applied potential for stable global potentiostatic operation while the bifurcation, with it dynamic variations in overpotential and dissipative ohmic losses, evolve freely leading to pattern development. In contrast, galvanodynamic measurements enable the potential inversion associated with S-NDR critical systems to be revealed more directly by virtue of the single valued control points within the S-NDR region that enable a fixed deposition rate to be easily specified and maintained.

Non-linear effects arise from coupling resistive electrolyte losses with transport constrained suppressor adsorption and its subsequent disruption by metal deposition and occur in extreme bottom-up filling of TSVs. However, engineering the uncompensated resistance to optimize feature filling has largely remained unexplored.

Simulations of copper deposition in TSVs and trenches compare feature filling dynamics between galvanostatic and potentiostatic control modes with an adjustable uncompensated resistance. The computations are built upon a suppressor co-adsorption S-NDR model that has been previously shown to capture feature filling dynamics and the relevant critical behavior. The base case is potentiostatic deposition with a minimum uncompensated resistance, comparable to prior experimental systems, that results in a narrow window for bottom-up filling that is subject to self-termination, preventing complete filling of the TSVs and trenches examined. Systematic stepping of the applied potential to more negative values (i.e., potentiodynamic control) can be used to adjust the termination point to achieve the desired level of filling. Conventionally, optimized galvanostatic deposition enables stable filling of high-aspect ratio features for a limited range of applied currents with growth termination determined by coulometry. However, designing the system to have a larger uncompensated resistance, coupled with the associated increases in the applied potential, enables significant expansion of the operational window and void-free feature filling by a potentiostatic control mode. Morphological evolution during filling under these conditions is nominally akin to that seen for galvanostatic deposition and, with optimization, the height of self-termination can be adjusted to match the feature opening. Another attribute associated with optimized use of the uncompensated resistance is an improvement in the ability to fill both simple and complex trench arrays under a fixed applied potential. Interestingly, iterative filling of individual recessed features may occur within the array when applied potentials/currents are at the less reducing end of the hysteretic window. For galvanostatic control this has an interesting analogy to the bifurcation reactions on microelectrode arrays where the individual microelectrodes not only sequentially switch from the passive to active state as the applied current density is increased but can also exhibit oscillatory behavior.

### Computational Methods

Finite element method (FEM) computations are used to simulate copper electrodeposition in 2D axisymmetric annular and cylindrical through-silicon vias and 2D trench arrays. The dimensions of the annular TSV (Rᵢ=4 μm, Rₒ=9.5 μm, and H=56 μm) match those of prior experimental systems. Simpler cylindrical TSV were also examined having radii of R_{cyl}=5 μm and heights, H_{cyl}, ranging from 50 μm to 200 μm corresponding to aspect ratios from 5 to 20. Trench array were simulated in a 4×1 configuration with dimensions of trench width Wₜ=10 μm, trench height Hₜ=50 μm, and pitch Pₜ=20 μm between trench edges. More complex trench arrays having a 3×1 configuration with varying trench width from 10 μm to 30 μm and trench height from 50 μm to 100 μm were also examined. For all workpiece geometries, the reference and counter electrode were combined in a common plane opposite the working electrode at a distance L, and the electric potential is fixed at zero. For the base case, L was taken to be 0.25 cm, thereby specifying the uncompensated resistance between the working and reference electrode. The hydrodynamic boundary layer thickness δ is set to 25 μm in all simulations and the concentration of each species (Cu²⁺, Cl⁻, and polymer) is set equal to that of the bulk solution (Cᵢ⁰) at these boundaries. The solution conductivity κ for the 1.0 mol/L CuSO₄—0.5 mol/L H₂SO₄ equals 15.26 S/m. Each simulation begins with a 2 min incubation period that emulates an experimental setup where patterned electrode fragments are pretreated with an ethanol wetting solution prior to insertion into the plating solution. Computationally, this is approximated with an applied potential of −0.40 V (or current equal to 1% of the set value) for 2 min before stepping to the set value. Initial concentrations are 0.01Cᵢ^{b} in the electrolyte domain below the hydrodynamic boundary layer to emulate electrolyte exchange with the ethanol filled features.

Variation in the uncompensated resistance between the reference and working electrodes was examined using three different schemes: (a) alteration of the distance between the reference and working electrodes, (b) insertion of a baffle into the electrolyte phase with fine scale porosity that effectively increases the resistance between the working and reference electrodes, and (c) insertion of an external resistor between the sensing point on the working electrode and the actual metal/electrolyte interface. All three approaches have been used by experimentalists for various ends. The first provides a simple method to evaluate the effect of the electrochemical cell time constant (t˜RC) while a baffle has been used in commercial electroplating cells to counter the terminal effect that otherwise leads to non-uniform deposition on resistive seed layers. The last approach, namely the introduction of the external resistor in series with a 2-electrode cell, has been used to examine the effects of variation in the experimental control mode, from potentiostatic to galvanostatic, and its impact on pattern formation in bistable systems.

The impact of uncompensated resistance on via filling was examined using the three different configurations outlined above. Given the symmetry of the cell and workpiece, despite differences in the location of the uncompensated resistance within the cell, the net effect on feature filling is the same, provided that the baffle is located sufficiently far from the working electrode to not influence the development of chemical gradients. Increasing the uncompensated resistance relative to that for the default geometry is investigated. Considering the uncompensated ohmic drop in the context of the electrolyte conductivity and the geometric configuration of the cell, with the working and counter electrode positioned at opposite end of circular tube of radius R_{c}, allows the ohmic losses due to current flow in the electrolyte to be defined by

$${Ω}_{s} = \frac{L}{π {R}_{c}^{2} κ} . \qquad [ 1 ]$$

For a given workpiece, area is taken to define the cross sections of the cell (i.e., πR_{c}²) so that changes in Ωs are accomplished by adjusting the position of the RE/CE, L, or through the solution conductivity, κ. A series of calculations were performed where Ωₛ is increased by a factor of 6×, 9×, 11×, 21×, 41×, 81×, 161×, or 401×. This can be realized by an increase in L from 0.25 cm to 1.5 cm, 2.25 cm, 2.75 cm, 5.25 cm, 10.25 cm, 20.25 cm, 40.25 cm, and 100.25 cm, respectively. Alternatively, the same effect can be obtained, perhaps more conveniently, by holding L at 0.25 cm and increasing the effect of K by insertion of a porous but insulating baffle whose net effect on ohmic losses is a composite of the respective materials properties. This is realized by making a slice of the electrolyte adjacent to the RE/CE plane having a thickness of 25 μm have a conductivity smaller, e.g. 500× to 20,000×, than that of the actual electrolyte conductivity, κ, effectively increasing the uncompensated resistance, e.g. by factor of 11× to 201×, greater than the default Ωₛ based on the homogenous κ solution resistance and L=0.25 cm. Going further, the same effects can be obtained, again perhaps more conveniently, by inputting an external resistor, that is some multiple of Ωₛ, between the WE and RE contacts (or CE/RE plane in the current construct). In fact, as long as the equivalent total cell resistance is the same, simulations produce identical results regardless of which method for adjusting resistance as outlined above is implemented. Nevertheless, of the three methods, adjusting the position of the RE/CE plane is the most computationally demanding as it requires additional meshing that leads to longer computational times. From an experimental standpoint, integrating uncompensated resistance as a variable control parameter into an existing 2- or 3-electrode system is most easily realized by the external resistor approach. As such, all simulations presented herein use an external resistor to adjust the overpotential to account for the potential drop associated with the deposition current flowing the external series resistor in order to model the impact of a modified global cell resistance.

The concentration Cᵢ and flux Nᵢ of each species in the electrolyte domain is described by the Nernst-Planck equation, capturing both diffusion and electromigration, such that the evolution of concentration is given by

$$\frac{{dC}_{i}}{dt} = - ∇ \cdot {\vec{N}}_{i} = - ∇ \cdot ( - {z}_{i} {u}_{m , i} {FC}_{i} ∇ ϕ - {D}_{i} ∇ {C}_{i} ) \qquad [ 2 ]$$

given the species' charge zᵢ, diffusion coefficient Dᵢ, Faraday's constant F, and mobility u_{m,i} calculated by the Einstein relationship

$${u}_{m , i} = \frac{{D}_{i}}{R T} . \qquad [ 3 ]$$

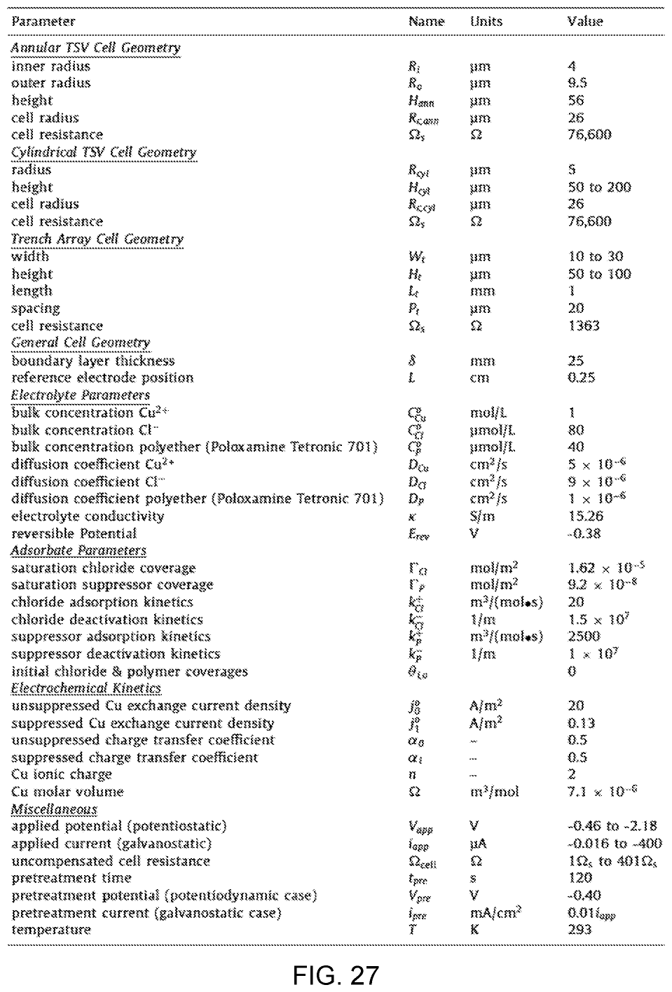

The simulated electrolyte assumes full dissociation of CuSO₄ and NaCl, reasonable for the relevant concentrations Cu²⁺ and Cl⁻, ignoring hydronium, sulfate, bisulfate, and sodium species. The poloxamine suppressor (subscript P) is assumed to be neutral in charge (zₚ=0). Diffusion coefficients listed in FIG. 27 for Cu²⁺, Cl⁻, and poloxamine tetronic (TET) are taken or estimated from literature sources.

Due to the high concentration of CuSO₄ and H₂SO₄ supporting electrolyte, potential in the electrolyte (ϕ) is well approximated by Laplace's equation

$${∇}^{2} ϕ = 0 , \qquad [ 4 ]$$

which neglects potential variation in solution arising from ionic gradients. The current density [symbol] associated with the Cu²⁺ flux through the electrolyte is given by Ohm's law

$$\vec{J} = - κ ∇ ϕ . \qquad [ 5 ]$$

where κ is the solution conductivity. A zero flux symmetry condition is imposed on the side of the cell (at r=R_{c} in axisymmetric simulations and x=0 and x=12 Wₜ in 2D simulations) for gradients of solution potential

$$\frac{\partial ϕ}{\partial r} = 0 , or \frac{\partial ϕ}{\partial x} = 0 \qquad [ 6 ]$$

and gradients of concentration

$$\frac{\partial {C}_{i}}{\partial r} = 0 , or \frac{\partial {C}_{i}}{\partial x} = 0. \qquad [ 7 ]$$

Accumulation of adsorbates on the electrode follows Langmuir adsorption kinetics with deactivation of suppression related to metal deposition involving a combination of desorption and/or incorporation into the growing deposit. Evolution of the fractional chloride coverage θ_{Cl}, defined as the surface concentration divided by the saturation coverage, is described by

$$\frac{d {θ}_{Cl}}{dt} = {k}_{{Cl}^{}}^{+} {C}_{Cl} ( 1 - {θ}_{C l} ) - {k}_{Cl}^{-} {θ}_{C l} v \qquad [ 8 ]$$

where k_{Cl}⁺ is the adsorption rate constant, C_{Cl} is the chloride concentration at the evolving metal/electrolyte interface, k_{Cl}⁻ is the deactivation rate constant and u is the metal deposition rate. Evolution of the fractional poloxamine coverage θ_{P}, is described by the analogous

$$\frac{d {θ}_{P}}{dt} = {k}_{P}^{+} {C}_{P} ( {θ}_{Cl} - {θ}_{P} ) - {k}_{P}^{-} {θ}_{P} v \qquad [ 9 ]$$

where the poloxamine is restricted to adsorption on top of the halide covered sites and thereby implicitly subject to the requirement that θ_{P} cannot exceed θ_{Cl} through adsorption. The fractional chloride and poloxamine coverages are further limited to values between 0 and 1. Values for kᵢ⁺ and kᵢ⁻ listed in FIG. 27 are estimated from model fits to the S-NDR voltammetry with the fitting procedure focused on capturing the critical onset potential for suppressor breakdown as a function of suppressor and halide concentration.^{20,44} In previous efforts the critical breakdown potential was shown to be dominated by the higher rate of Cl⁻ adsorption and consumption relative to that of the polymer. Once a fully developed Cl-polyether adlayer exists, Cl⁻ consumption into the solid by the second term in Eq. 7 can make the adsorption term for the suppressor in Eq. 8 function effectively as a desorption term.

The metal deposition rate is assumed to be a function of the suppressor coverage θ_{P} (or equivalently, coverage of the polyether-chloride bi-layer), metal ion concentration C_{Cu}, and overpotential η at the interface, thus

$$v ( {θ}_{P} , {C}_{Cu} , η ) = \frac{Ω}{n F} \frac{{C}_{Cu}}{{C}_{Cu}^{o}} [ {j}_{θ = 0} ( η ) ( 1 - {θ}_{P} ) + {j}_{θ = 1} ( η ) {θ}_{P} ] . \qquad [ 10 ]$$

The current densities on unsuppressed (j_{θ=0}) and suppressed (j_{θ=1}) surfaces for the two electron reduction of Cu²⁺ to its metallic form are translated into growth velocity, u, using Faraday's constant (F=96,485 C-mol⁻¹), the ionic charge n, and the molar volume Ω of solid copper. This simple form captures suppression arising from the polyether coverage (as limited by chloride coverage). The current densities (j_{θ=0.1}) are assumed to exhibit the conventional exponential dependence on overpotential q by

$${j}_{θ = 0 , 1} ( η ) = {j}_{θ = 0 , 1}^{o} ( {e}^{\frac{( 1 - {α}_{θ = 0 , 1} ) F}{RT} η} - {e}^{\frac{{α}_{θ = 0 , 1} F}{RT} η} ) . \qquad [ 11 ]$$

The applied potential Vₐₚₚ is related to the working electrode through

$${V}_{app} = η + ϕ + {E}_{r e ν} \qquad [ 12 ]$$

where the potential ϕ within the electrolyte is evaluated at the electrolyte/deposit interface to capture the dissipative losses between the workpiece and the reference electrode associated with current flow through the electrolyte and external resistor layer. The overpotential driving electrodeposition is referenced to the reversible Nernst potential for the Cu²⁺/Cu reaction. The values of j_{θ=1}⁰ and α_{θ=1} for the fully suppressed surface are obtained by fitting the negative-going voltammetric scans up to the onset of suppression breakdown. Although the kinetics of metal deposition on polymer-free surfaces are known to be a function of halide coverage, for simplicity, the present work uses a single set of j_{θ=0}⁰ and α_{θ=0} values for deposition on the polymer-free surface.

The local current density at the electrode is equated to the Cu²⁺ flux from the electrolyte onto the electrode interface (outward surface normal \hat{n}) according to

$$\frac{1}{n F} {\vec{J}}_{Cu} \cdot \hat{n} = - ( {z}_{Cu} {u}_{m , Cu} {FC}_{Cu} ∇ ϕ + {D}_{Cu} ∇ {C}_{Cu} ) \cdot \hat{n} . \qquad [ 13 ]$$

Similarly, the normal fluxes of chloride and polyether from the electrolyte to the interface are equated to the rates of their adsorption yielding

$$- ( {z}_{Cl} {u}_{m , Cl} {FC}_{Cl} ∇ ϕ + {D}_{Cl} ∇ {C}_{Cl} ) \cdot \hat{n} = {Γ}_{Cl} {k}_{Cl}^{+} {C}_{Cl} ( 1 - {θ}_{Cl} ) \qquad [ 14 ]$$

with saturation coverages Γᵢ estimated. As stated previously, the (θ_{Cl}−θ_{P}) term captures the requirement that suppressor adsorption only occurs at chloride covered surface sites.

The full system of equations is solved numerically in 2D and 2D-axisymmetric geometries using a finite element method employed in the COMSOL Multiphysics version 5.5 software package with the default solver, implementing the following modules: tertiary current distribution, primary current distribution, separate coefficient form boundary partial differential equations for both chloride and suppressor, and deformed geometry. The 2D triangular mesh elements are more highly refined along the electrode interface, their dimensions initially equal to 20% of the feature radius or width on each side. The mesh scales up to a maximum of 2.5 μm within the boundary layer and 26 μm outside of the boundary layer. The mesh in the thin resistive layer is also refined, having a maximum size of 5.2 μm. Automatic remeshing is enabled, prompting re-mesh when the maximum mesh distortion parameter exceeded 1.56. A moving boundary smoothing parameter of 2, geometry shape order of 1, and Laplace mesh smoothing type are used in the deformed geometry module (see COMSOL documentation for detailed explanation on how these parameters impact moving boundary convergence). The system of equations was solved so that the overall charge imbalance (the fractional difference between the total integrated currents at the counter and working electrodes) was less than 0.02%. The numerical evaluation error, thus, is acceptably small for the present purposes. To give a sense of the computational expense, the smaller geometry simulations having 1800 domain and 400 boundary mesh elements take on the order of 5 minutes to compute. Larger simulations having 5000 domain and 800 boundary mesh elements takes on the order of 30 minutes to compute. All simulations used a Dell Precision 3630 desktop computer with an Intel Xeon E-2186G CPU @ 3.80 GHz and 64 GB RAM using a Windows 10 Enterprise 64-bit operating system.

### Results and Discussion

Experimental copper deposition in through-silicon vias (TSV) in electrolytes having a single suppressing polyether additive for a range of chloride concentrations (2 μmol/L to 1000 μmol/L) and combinations of CuSO₄ and H₂SO₄ concentrations were performed. In low chloride solutions (s 80 μmol/L), copper deposition initially occurs on the bottom of the via as well as the neighboring sidewalls up to a position marking a transition between active and passive plating regions. This transition point shifts upward in the via with lower chloride concentrations or more negative potentials. At fixed potential, deposition is eventually quenched at a position within the via determined by the balance between transport constrained adsorption of the suppressing additives and its disruption by the metal deposition reaction. Thus, for these low chloride electrolytes it is necessary to step or ramp the potential to more negative values in order to fully fill features. This approach requires tuning of the applied potential waveform to optimize filling. For stepped potentials, the discontinuous nature of the increase in available free energy might be expected to impact, or at least mark, the deposit microstructure. Galvanostatic deposition provides both operational simplicity and cost advantages in process control, congruent with its use in industrial electroplating practice. Deposition is sustained as long as the current is applied and with proper optimization void free filling is possible. If the applied current is too high void formation will occur while too low a value will result in uneven activation of deposition across the workpiece. Even with an appropriate value of applied current substantial under- or overfill will occur if the deposition time is not tuned appropriately for each substrate pattern. Alternatively, the spontaneous self-passivation associated with potential-controlled deposition offers an alternative path to feature filling that should be less sensitive to variations in pattern density on the work piece.

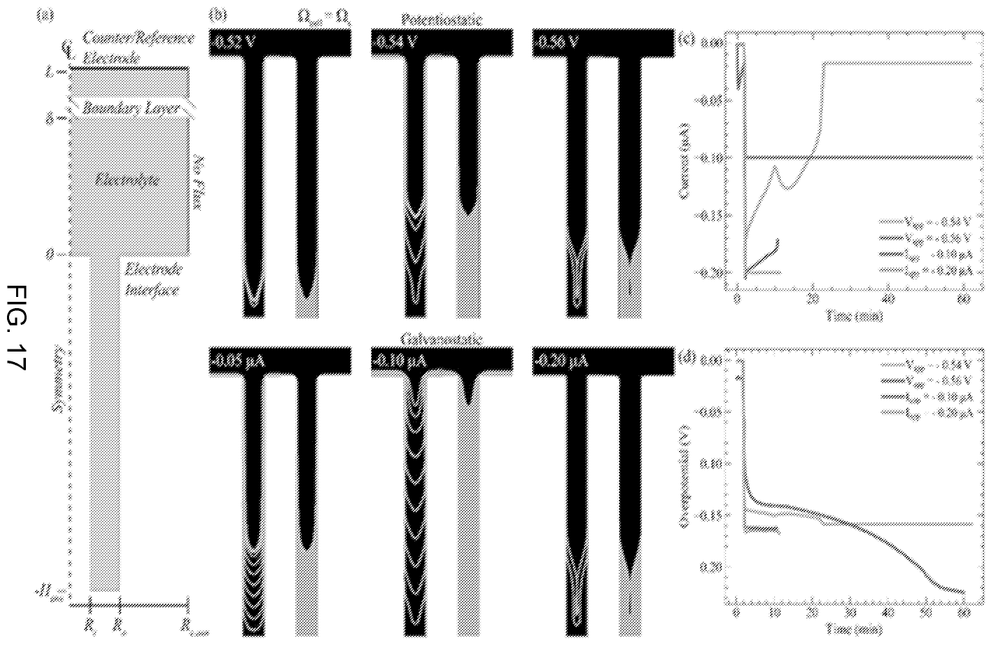

Simulations in annular TSV—FIG. 17 shows simulated final growth profiles and interface contours (in 6 min intervals) for potentiostatic and galvanostatic deposition in 1 mol/L CuSO₄, 0.5 mol/L H₂SO₄, 40 μmol/L TET, and 80 μmol/L Cl− for the annular TSV configuration shown schematically in FIG. 17a. The cell and workpiece geometry has been previously detailed both experimentally and computationally for potential-controlled deposition with L=0.25 cm. Simulations of potentiostatic deposition do not predict complete filling even under conditions yielding deposition localized to the via bottom, rather passivation occurs less than halfway up the via after ≈20 min at −0.54 V. Deposition at −0.52 V passivates even earlier, after ≈6 min, filling just the lowermost 4 μm of the 56 μm tall feature. At a more reducing potential of −0.56 V deposition is predicted to yield void formation after 8.5 min. Galvanostatic deposition, conversely, results in a nearly filled feature at −0.10 μA after 1 hour of deposition with the applied current appropriately tuned to the relevant electrochemically active surface area in the present case. A factor of 2 decrease in the applied current results in only ⅓ of the feature being filled after 1 h before localized bottom-up deposition is lost and the applied current redistributes across the entire surface corresponding to a 7× decrease from peak current density during bottom-up fill. At the other limit, a doubling of the applied current produces a void after 9 min.

FIG. 17 shows (a) a schematic of the axisymmetric geometry used in the S-NDR model to simulate deposition in the annular TSV with dimensions of Ri=4 μm, Ro=9.5 μm, and Hann=56 μm. Relevant domains and boundaries are indicated. (b) Simulated growth contours in 6 min intervals (left-hand via) and final deposit positions (right-hand via) for potentiostatic (top) and galvanostatic (bottom) copper electrodeposition after 1 h at the indicated operating conditions. (c) Current and (d) overpotential, r, transients for the indicated simulations presented in (b). Full seam-free and void-free filling can only be obtained for a narrow window of galvanostatic deposition conditions and is not obtainable at all for potentiostatic conditions.

Current and potential transients in FIG. 17c and FIG. 17d, respectively, provide insight into the growth dynamics under potentiostatic deposition at −0.54 V and −0.56 V for the base case with an uncompensated resistance of 1 Wₛ and, for the same geometry, galvanostatic deposition at −0.10 μA and −0.20 μA. The appropriate area for current density scaling is somewhat of a mystery for bifurcating systems with a temporally varying total electrode area. That said, an applied current of −0.10 μA corresponds to −4.7 mA/cm² when scaling by projected electrode area, −42.9 mA/cm² when using only the via bottom, and −1.45 mA/cm² when using the entire electrode interface, signifying the available current density range depending on what is truly the electrochemically relevant surface area. Each simulation begins with a 2 min incubation period to emulate experiments where the electrolyte mixes with an ethanol wetting solution, as described in detail in the preceding section. After stepping to −0.54 V the current sharply rises to −0.17 μA followed by a slow decent associated with Cu²⁺ depletion as deposition begins on the bottom surface and the adjacent sidewalls. This is followed by a current inflection near 10 min that correlates to the area reduction of the growth front during the transition from conformal deposition on the via bottom and adjacent sidewalls to bottom-up filling, evident in growth front profiles at 6 and 12 minutes shown in FIG. 17b. Following the brief rise in current to reach a local maximum near −0.13 μA the onset of passivation begins as the suppressor phase reforms and the current descends to a final passive current plateau of ≈−0.02 μA for the workpiece. Stepping to a more aggressive applied potential of −0.56 V leads to an initial current in excess of −0.20 μA followed by a slow current decay for the first few minutes as depositions develops in the lower sidewalls and via bottom; however, the resulting Cu²⁺ depletion followed by sidewall collision results in void formation by 9 min which halts further simulation. In the galvanostatic simulations, the applied potential (and thus overpotential) of the working electrode varies with time. For deposition at −0.10 μA the overpotential transient exhibits a gradual increase as bottom-up filling of the via progresses to almost fill the via by 1 h. The increase in driving force is required to sustain the applied current in the face of increased suppressor flux as the unfilled via depth shrinks and gradient becomes steeper. A doubling of the applied current to −0.20 μA yields a high overpotential close to −0.16 V that remains constant during a period of conformal growth on the lower sidewalls and bottom surface until sidewall impingement and void formation halts the simulation, analogous to the case for potentiostatic deposition at an excessively negative applied potential of −0.56 V.

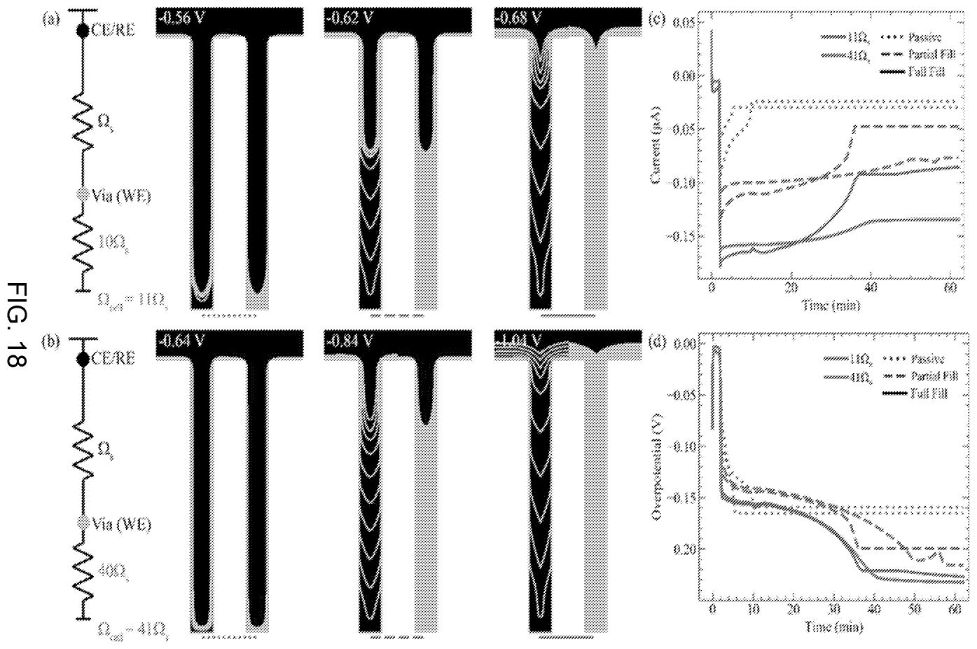

FIG. 18 shows simulated final growth profiles and positional contours (in 6 min intervals) for potentiostatic deposition in the annular TSV depicted in FIG. 17a but with an additional uncompensated resistance equal to (a) 10Ωₛ, and (b) 40Ωₛ (corresponding to 11× and 41×, respectively, higher total cell resistance relative to the base case). For both conditions, it is evident that the increase in resistance permits more complete filling of the annular TSV at a constant applied potential following 1 h of deposition. As with galvanostatic deposition in FIG. 17, the applied potential must be chosen appropriate to the pattern density and geometry but, significantly, by appropriate engineering of the uncompensated resistance full bottom-up filling can be accomplished at a fixed applied potential, analogous to earlier TSV filling albeit at higher CI-concentrations.¹⁸ At potentials that are too positive the system fails to activate and the current is distributed uniformly across the passivated surface; at the other extrema, when the applied potentials are too negative, a seam or void is formed. Simulations (not shown) reveal that applied potentials 20 mV more negative than those shown in FIG. 18 result in seams or voids. It is also noteworthy that the potential window between complete interface passivation and voided via is significantly widened with the increase in uncompensated resistance, shifting from 40 mV (for partial bottom-up filling as in FIG. 1) for the base case with no added resistance (1 Ωₛ) to 140 mV and 420 mV with total uncompensated cell resistances equivalent to 11 Ωₛ and 41 Ωₛ, respectively. Further still, one can readily envision tuning the resistance and/or applied potential such that deposition passivates just before the via outlet, a phenomenon difficult to achieve by a galvanostatic approach.

In an embodiment FIG. 18 shows simulated growth contours in 6 min intervals (left-hand via) and final interface positions (right-hand via) for potentiostatic copper deposition in the annular via at the indicated potentials with an increased system resistance equivalent to (a) 11× and (b) 41× the system resistance associated with the electrodeposition composition in the cell alone, Ωs. Schematics show a 1-D representation of the resistances in the circuit. Corresponding (c) current and (d) overpotential, η, transients are included for the passive (−0.56 V, −0.64 V), partial fill (−0.62 V, −0.84 V) and full fill (−0.68 V, −1.01 V) characteristic deposition profiles. Use of sufficiently large system resistances permits seam-free and void-free filling at −0.68 V and −1.04 V under potentiostatic conditions. The increased system resistance may be obtained using an external resistance, a semipermeable or permeable resistive baffle or membrane or expanding a distance (800) between the reference (500) and substrate (600) electrode, in FIG. 15 and FIG. 16.

The current and overpotential transients associated with the filling simulations are shown in FIG. 18c and FIG. 18d, respectively, categorized as passive, partial fill, or full fill according to the final deposition profiles (left, middle, and right, respectively, of FIG. 18b). In each case the current spikes to a more negative value after the initial 2 min incubation period. The current gradually falls as the via is filled; current reduction occurs faster for lower applied potentials and for the smaller value of uncompensated resistance. At less reducing applied potentials (passive, shown as dotted lines . . . ), the more rapid current reduction ends with universal interface passivation and sustained deposition currents near −25 nA that are distributed over the remaining deposit surfaces for both values of uncompensated resistance. The small difference in the final current, for the −0.56 V and −0.64 V examples, reflects the more negative overpotential for the latter as evident in the respective transients shown in FIG. 18d; both profiles rise quickly to ≈−0.16 V and −0.165 V, respectively, at which value they remain constant for the duration of the 1 h simulation. The transients for the intermediate applied potentials (partial fill, shown as dashed lines ---) exhibit a more gradual reduction in current after the initial spike (FIG. 18c), plateauing after 35 min of deposition for the 11 Ωₛ case and 55 min for the 41 Ωₛ case (the latter evident in plots extending to longer times). The current in the simulation with a total uncompensated cell resistance of 11 Ωₛ decreases (in magnitude) by about 0.06 μA while that for 41Ωₛ decreases by about 0.02 μA. The more stable current profile for a higher cell resistance reflects the transition towards galvanostatic control. Interestingly, the current transients at intermediate (---) and more negative (full fill, shown as solid lines -) applied potentials exhibit similar trends, with the latter shifted to larger current values. With 11 Ωₛ of uncompensated resistance, the current plateaus at a similar time for both applied potentials. The higher current at −0.68 V yields more sustained localized deposition that results in a fully filled via. With 41 Ωₛ of uncompensated resistance, continued motion explicit in the last two growth contours at −0.84 V suggests that the feature might fill completely given sufficient deposition time. The simulation at −1.04 V reaches the field (i.e., z=0) sooner because of the higher overall current throughout the process (although it is clear that more material is also deposited on the field). It is notable that the overpotential profiles for both full fill simulations, i.e., at −0.68 V with 11Ωₛ and at −1.04 V with 41Ωₛ, are nearly identical for the entirety of the simulations. With filling contours that are quite similar almost through full filling, it is understood that the trend reflects the increased driving force required to advance the growth front nearer the via opening due to the enhanced transport of the suppressing additives and despite the increased transport of metal ion.

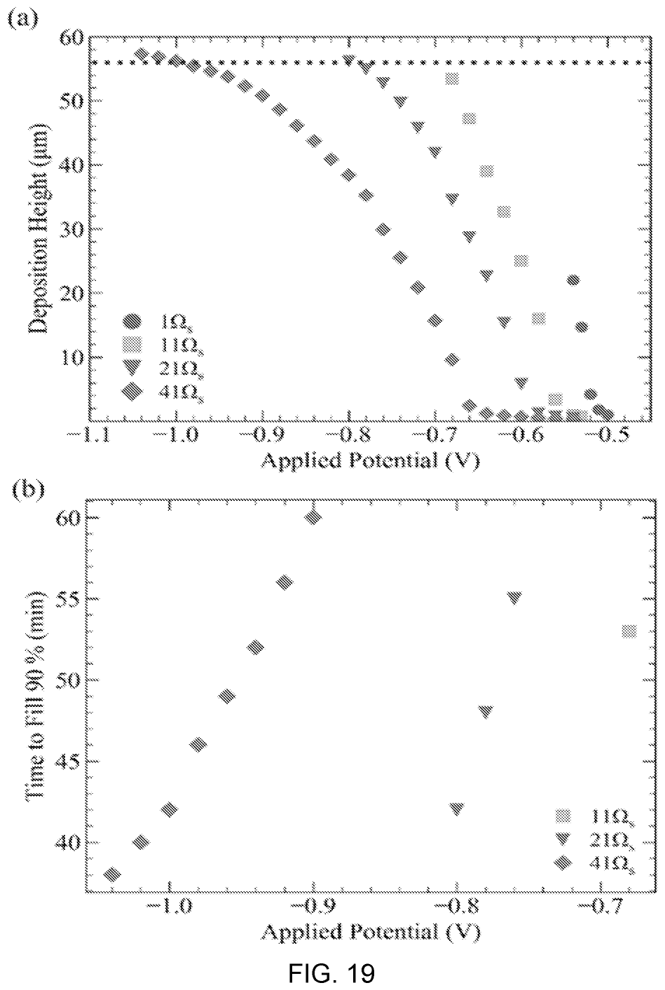

Simulations of the impact of uncompensated resistance on the filling of the annular TSVs were expanded to explore the full range of applied potentials between passive and voided growth profiles and include an intermediate value for total uncompensated resistance of 21 Ωₛ. FIG. 19a shows the lowest position on the TSV interface after 1 h of deposition for the indicated uncompensated resistances as a function of applied potential. As seen in FIG. 17, potentiostatic control with 1 Wₛ uncompensated resistance only achieves a fill height of 23 μm before the next −20 mV increment of applied potential results in void formation. Increasing the uncompensated resistance expands the applied potential window between fully passive and voided filling while also permitting higher possible fill heights for constant potential simulations; the interval ranges from positive of −0.7 V to negative of −1.0 V, more than 0.3 V, with 41 Ωₛ of total uncompensated resistance as reflected in the data in FIG. 19a. The impact of each −20 mV increment decreases at more negative applied potentials particularly for the 41 Ωₛ data. The curve reflects the balance of transport, which scales with the concentration gradients and thus increasing with 1/unfilled depth (i.e., increasing asymptotically as deposition height approaches via depth), with the potential dependent deposition kinetics that drives disruption of the suppressor layer. FIG. 19b plots the time needed to achieve 90% fill of the annular TSV as a function of the applied potential for each resistance. Higher uncompensated resistance also enables faster filling of the TSV, reaching 50.4 μm of height as quickly as 38 min for 41 Ωₛ, 42 min for 21 Ωₛ, and 53 min for 11 Ωₛ. As in FIG. 18, decreased fill time with increased uncompensated resistance is associated with more stable operating currents throughout filling consistent with a trend towards galvanostatic operation.

FIG. 19 Panel (a) shows a chart of the lowest position (at the centerline due to symmetry) on the annular TSV interface after 1 h of deposition as a function of applied potential for the indicated increased system resistance. Simulations 20 mV more negative of the most negative potentials shown for each resistance result in a seam or void. The dashed line represents the deposit height for a fully filled via. FIG. 19 Panel (b) shows a chart of the time needed for filling along the centerline to reach 90% of the via height plotted as a function of applied potential for the indicated uncompensated cell resistance. Simulations requiring more than 60 min deposition time to achieve 90% fill are not included. The increased system resistance broadens the range of applied potentials yielding seam-free and void-free filling, including filling that passivates near the field surface. The increased system resistance can be obtained using an external resistance, a semipermeable or permeable resistive baffle or membrane or increased separation between the reference and substrate.

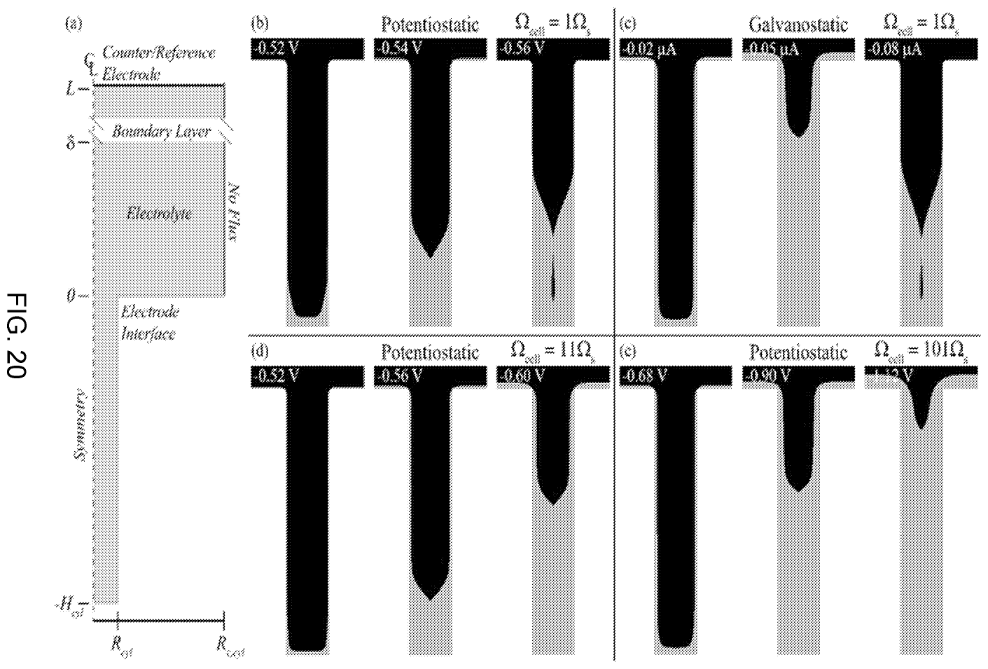

Simulations in cylindrical TSV—The simulations of deposition in annular TSV in the preceding section offer prediction that can be validated against prior experimental work.²⁰ This section explores the influence of uncompensated resistance on deposition in the more generic cylindrical TSV geometry depicted in FIG. 20a. Similar to the annular TSV, simulations of potentiostatic deposition with 1 Ws uncompensated resistance (again, determined by L=0.25 cm and R_{c} by Eq. 1) in the 5 μm radius and 50 μm tall via in FIG. 20b depict a narrow operating window between passive (−0.52 V) and voided (−0.56 V) growth profiles. Achieving a fully filled cylindrical TSV again requires a potentiodynamic waveform that progressively shifts the location of the sidewall passive-active transition upwards like that detailed in previous work. As with the annular TSV, galvanostatic deposition enables void-free bottom up via filling that is almost complete after 1 h of deposition at an applied current of −0.05 μA as shown in FIG. 20c. However, closer inspection (not shown) reveals that the majority of the via is filled in the first 30 minutes of deposition before additive transport is sufficient to passivate deposition and shift much of the current towards deposition on the TSV field. Of course, galvanostatic methods still require tuning of the applied current to avoid conformal, passive deposition on the via (as at −0.02 μA) or voided deposits (as at −0.08 μA). FIGS. 20d and 20e show simulations of potentiostatic deposition with an increase in uncompensated resistance to 11Ωₛ and 101Ωₛ, respectively. As with the annular geometry, simulations with the additional uncompensated resistance predict higher filling within the cylindrical TSV for the given electrolyte chemistry. After 1 h, the deposit height reaches −22 μm for the 100s case at −0.60 V and −8 μm for the 1000s case at −1.12 V. For each resistor, the simulations at potentials 20 mV more negative than these values predict a seam or void.

FIG. 20 shows (a) a schematic of the axisymmetric geometry used in the S-NDR model to simulate deposition in a cylindrical TSV with dimensions of Rcyl=5 μm and Hcyl=50 μm. Relevant domains and boundaries are indicated. Simulated growth profiles for (b) potentiostatic and (c) galvanostatic copper electrodeposition after 1 h at the indicated applied potentials and currents with 10s of system resistance. Simulated growth profiles after 1 h of potentiostatic copper electrodeposition with system resistance of (d) 11 Ωₛ and (e) 101Ωₛ. Only potentiostatic deposition with the increased system resistance permits seam-free and void-free filling that approaches near the field surface. The increased system resistance may be obtained using an external resistance, a semipermeable or permeable resistive baffle or membrane or increased separation between the reference and substrate.

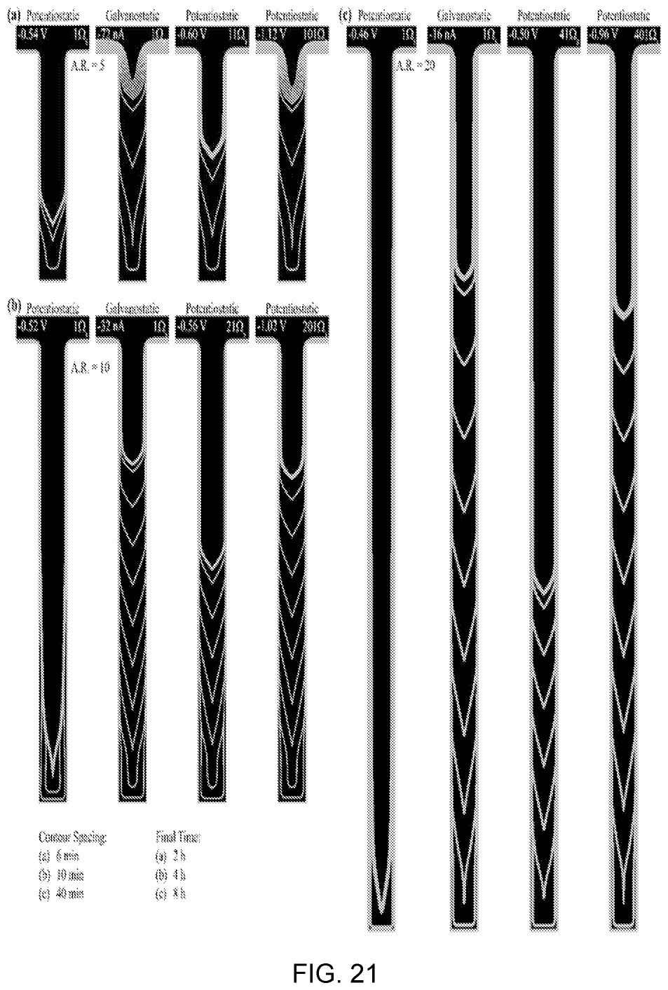

The interesting behaviors uncovered thus far motivated further exploration of the effect of uncompensated resistance on the filling of even higher aspect ratio features. FIG. 21a shows simulated growth contours in 6 min intervals for the indicated control-method, operating condition, and added uncompensated resistance for the cylindrical TSV geometry presented in FIG. 20a (having an aspect ratio of 5). The potentiostatic deposition at −0.54 V for a cell with 1 Wₛ passivates shortly after 12 minutes of deposition, having achieved a deposit height of only 12 μm. Note, each condition presented in FIG. 21 is the most reducing applied potential or current before simulations produce a seam to a resolution of 20 mV and 2 nA intervals. Galvanostatic deposition at −72 nA permits active bottom-up deposition within the via for 24 minutes before shifting to a slower conformal deposition mode where the last 30 minutes of deposition only results in the addition of 3.5 μm to the 43 μm tall deposit. This tuned current corresponds to current densities of −3.39 mA/cm² when scaled by projected area, −91.7 mA/cm² when scaled by area of the via bottom, and −1.95 mA/cm² when scaled by the entire electrode interface. For potentiostatic deposition with 11Ωₛ of uncompensated resistance an applied potential of −0.60 V yields maximum filling with active deposition for ≈21 min before full passivation occurs. Potentiostatic deposition with 101Ωₛ of total uncompensated resistance and an applied potential of −1.12 V yields maximum filling with a profile that is remarkably similar to that for galvanostatic deposition at −72 nA; a shift from bottom-up growth to conformal deposition occurs after 24 min.

FIG. 21 shows simulated growth contours for a cylindrical TSV with a 5 μm radius and heights of (a) 50 μm, (b) 100 μm, and (c) 200 μm for the indicated applied potentials/current and system resistance. Final contours are at 1 h, 2 h, and 8 h with contour spacing of 6 min, 10 min, and 40 min for TSV with heights of 50 μm, 100 μm, and 200 μm, respectively. The specified applied potentials are the most negative values that do not result in seam or void formation and thus reflect the highest filling along the via centerline obtained for the given value of system resistance (in increments of 20 mV). Neither galvanostatic nor potentiostatic deposition alone are capable of providing seam-free and void-free filling that approaches near to the field surface in the vias having the higher aspect ratios of 10 and 20, but higher system resistance enables higher filling and the broadest potential window and essentially matches the highest filling that can be obtained using a narrow window of currents. The increased system resistance may be obtained using an external resistance, a semipermeable or permeable resistive baffle or membrane or increased separation between the reference and substrate.

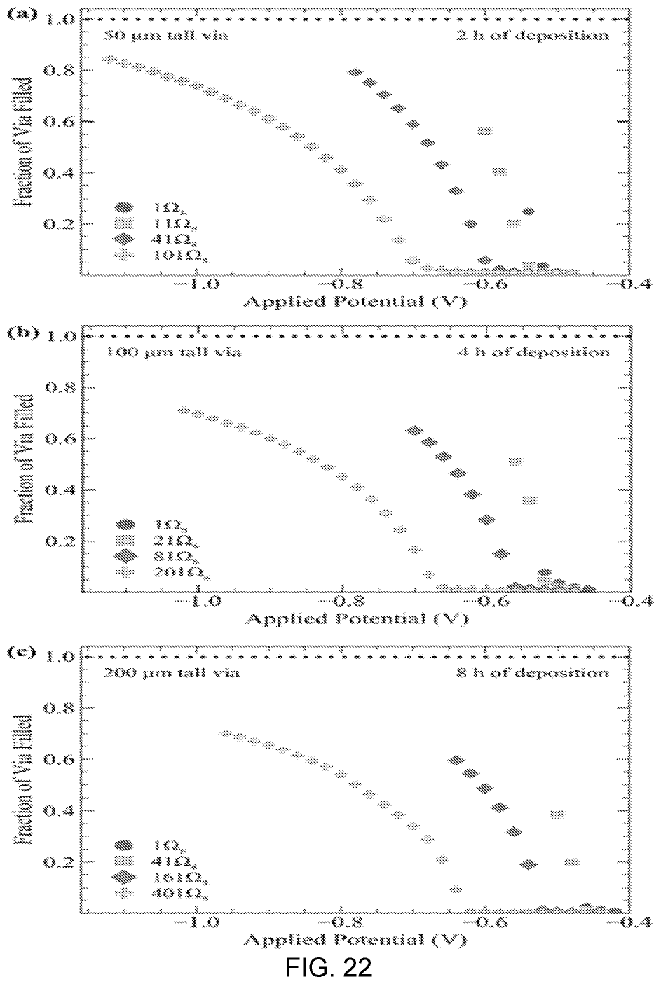

A sequence of simulations are presented for deeper cylindrical TSVs having aspect ratios of 10 and 20 (R_{cyl}=5 μm) in FIGS. 21b and 21c, respectively. In general, the trends in deposition profiles across the control-methods and uncompensated resistance match those in FIG. 21a. Specifically, potentiostatic deposition with 1 Wₛ results in early passivation deep within the via whereas a substantially larger uncompensated resistance shifts the final deposit height higher, eventually approaching the height achieved using a galvanostatic approach for the largest values of uncompensated resistance. In higher aspect ratio vias the applied potential/current must be less reducing, regardless of control method or uncompensated resistance, to avoid Cu²⁺ depletion and formation of a seam or void. For galvanostatic deposition, the most reducing current is roughly halved for each doubling of the via depth, consistent with consideration of the gradient that underlies reactant and additive transport. In terms of current densities, the aspect ratio 10 and 20 features correspond to −1.51 mA/cm² and −0.75 mA/cm² when scaled by projected area, −40.7 mA/cm² and −20.4 mA/cm² when scaled by area of the via bottom, and −0.61 mA/cm² and −0.19 mA/cm² when scaled by the total electrode interface area, respectively. Despite the aggressive selection of applied potentials and currents, passivation occurs before the deposit reaches the field for each geometry. Although not the focus of this study, fill height would be improved by reducing the flux of suppressor additives by either decreasing chloride concentration or reducing convective transport (i.e., increasing the boundary layer thickness in the model). The final deposit height (lowest point on interface which, by symmetry, lies at the via middle) as functions of applied potential for the cylindrical vias with aspect ratios of 5, 10, and 20 are presented in FIGS. 22a, 22b, and 22c, respectively, for the indicated values of total uncompensated resistance. As with the annular geometry, the fill height for each geometry increases and the potential window between fully passive and voided filling profiles widens as the uncompensated resistance is increased. Curvature reflecting the balance between transport, with its asymptotic dependence on via depth minus fill height, with deposition rate dependent disruption of the suppressor layer is observed again as well.

FIG. 22 shows charts of the lowest centerline position on the cylindrical TSV interface as a function of applied potential for the indicated total cell resistances and deposition times for 5 μm radius TSV. Panel (a) for 50 μm, Panel (b) for 100 μm, and Panel (c) for 200 μm height. Higher values of system resistance permit higher filling over a broader range of applied potential. The increased system resistance may be obtained using an external resistance, a semipermeable or permeable resistive baffle or membrane or increased separation between the reference and substrate.

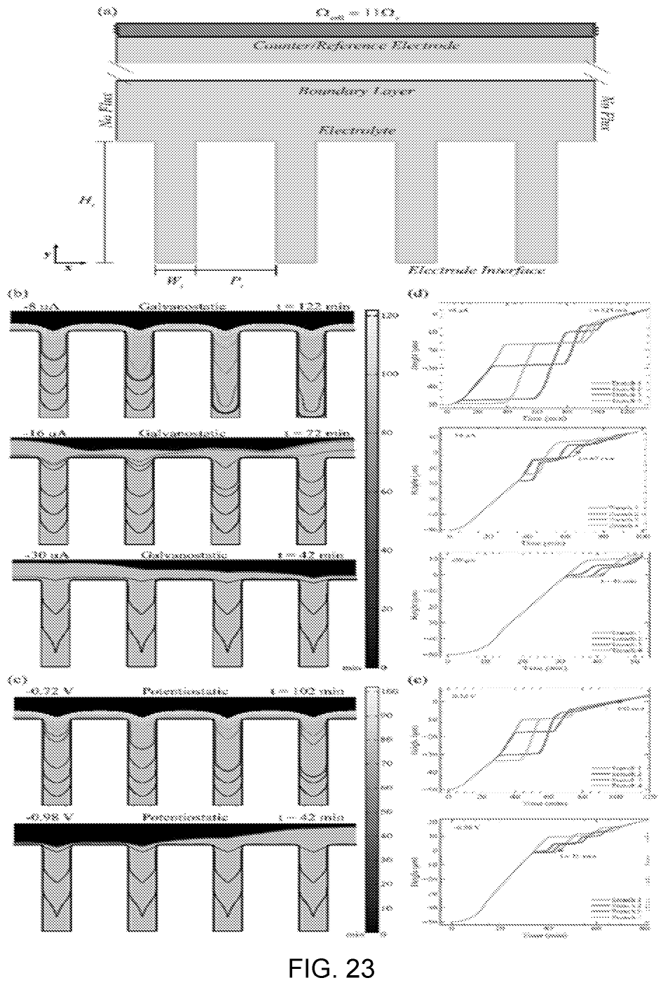

Deposition in trench arrays—The influence of uncompensated resistance on Cu deposition in high aspect ratio features was further explored in trench arrays as depicted in the 2D geometric configuration of FIG. 23a. Trenches are 10 μm wide, 50 μm tall, 1 mm deep (into the page), and are spaced 30 μm apart center-to-center (Pₜ=20 μm). Simulations of galvanostatic operation produce fully filled trench arrays at currents ranging from −6 μA to −30 μA, the major difference being the time necessary to achieve complete fill. Currents in excess of −30 μA produce voids towards the bottom of the trench while currents smaller than −6 μA result in conformal deposition over the entire electrode interface. For −30 μA of applied current, the current densities are −25 mA/cm² when scaling by projected area, −75 mA/cm² when scaling by the area of the trench bottom, and −5.77 mA/cm² when scaling by the entire electrode interface. Final deposit profiles and contours shown in FIG. 23b indicate the electrode interface position spaced in 10 min intervals for galvanostatic conditions that enable full filling. For all three conditions the trench array is completely filled, with deposition at −8 μA requiring 80 min longer than −30 μA. For the two higher applied currents the resulting overburden is non-uniform across the array. The interface contours (colorized to indicate time) show that deposition at −30 μA occurs uniformly in all 4 trenches from 2 min to 32 min. After this time, deposition is localized to the 1^{st} trench and shifts across the array from left to right. The charts in FIG. 23d show the center-line position as a function of time for each trench depicted in FIG. 23b. The profiles for all 4 trenches at −30 μA are identical until ≈32 min; shortly after this time, deposition continues in trenches 1 and 2 while trenches 3 and 4 have passivated. Eventually, the 3^{rd} and 4^{th} trenches reactivate and achieve a similar height across the array at 52 min of deposition. At t=41 min, all 4 trenches have reached the field (position of y=0), although a difference in height of ≈10 μm exists between trenches 1 and 4.

In an embodiment with multiple features on a single substrate FIG. 23 shows (a) a schematic of the 2-D geometry used in the S-NDR model to simulate deposition in trench arrays with dimensions of Wt=10 μm, Ht=50 μm, and Pt=20 μm, and length of 1 mm (into the page). Simulated growth profiles for (b) galvanostatic and (c) potentiostatic copper electrodeposition at the indicated operating conditions and final times with a system resistance of 11 Ωₛ. Contour lines represent the individual trench centerline positions of the electrode interface, spaced in 10 min intervals and beginning after the pretreatment step, colorized to indicate time. (d-e) Charts showing the centerline position of the growth front for each individual trench (denoted as T1, T2, T3, and T4 from left-to-right) as time progresses with annotations indicating the time when all trenches reach y=0. It is seen that complete seam-free and void-free filling of all four features occurs sequentially under galvanostatic conditions of smaller current and with substantial deposit on the field surface because active deposition shifts between the recessed features because deposition in the S-NDR electrodeposition composition is unstable to small perturbations under galvanostatic conditions of higher currents. Potentiostatic deposition with a small system resistance of 1 Ωₛ yields a very narrow process window, less than 20 mV, in which seam-free and void-free filling is obtained but with the larger system resistance of 11 Ωₛ shown here an increased potential range, 380 mV, an order of magnitude improvement, yields seam-free and void-free filling. The increased system resistance may be obtained using an external resistance, a semipermeable or permeable resistive baffle or membrane or increased separation between the reference and substrate.

Deposition at the lower applied current of −16 μA exhibits analogous behavior, although deviation of height among the trenches in the array begins at a lower height within the trench after ≈35 min. In this case, deposition dynamically passivates and re-activates within various trenches from 35 min to 95 min, at which point the profiles all merge again. Similar to the −30 μA condition, there is an a 10 μm difference in height between trenches 1 and 4 at t=67 min although in this simulation trench 1 is the last to reach the field (y=0). Deviation across the trench array occurs at even earlier times for a lower applied current of −8 μA, after only 3 minutes of deposition, and progresses in almost discrete steps, not unlike the sequential activation seen in the case of microelectrode arrays under controlled current where the total current is a globally conserved quantity. At 35 min the difference in height between trenches 1 and 4 is 34 μm. After 110 min the individual trenches have all reached roughly the same height, breaking the y=0 threshold at 124 min.

Inherent to the S-NDR system is competition between interface activation driven by disruption of the suppressor layer by metal deposition that is balanced against interface passivation driven by additive adsorption. In short, under galvanostatic control, higher applied currents for a given active area are associated with higher rates of deposition and increased suppressor disruption associated with halide incorporation at larger overpotentials. If the applied current is sufficiently high then transport limited passivation is insufficient to shut down deposition within the feature (suppressor flux being reduced deeper within a feature) and the deposition profiles across the array are uniform. However, the additive flux available to passivate active deposition in a feature increases as filling proceeds upward. At some point, variations in the geometry between the individual features, or its numerical simulation, occur such that a portion of the active interface can passivate and redistribute the current to other features. Subsequently the inverse can occur as well, where passive features reactivate and draw current from other sites. Such localized passivation and reactivation is the origin of the non-uniform profiles across the arrays in FIG. 23. Improved uniformity within the array at −30 μA relative to that at −16 μA and −8 μA reflects the higher suppressor flux required to passivate the surface when operating at the higher deposition (and adsorbate consumption) rates and correspondingly higher overpotentials, subject to the limits on additive transport defined principally by depth within the trench. For the value of applied current that yields localized deposition within the trenches there will necessarily be a depth at which the transport limited suppressor flux, scaling as the inverse of that depth, is sufficient to induce such instabilities. Eventually, however, the profiles all converge, indicating that the increased transport limit on suppressor flux is balanced by increased overpotential in a manner that enforces activation of all features. Both the passivation/activation of individual features and the ultimate convergence of filling contours in all features are clear for the −8 μA profile in FIG. 23b and are also evident at longer times in the FIG. 23d charts for −16 μA and −30 μA.

As with the annular and cylindrical vias shown earlier, simulation of trench array filling under potentiostatic conditions in the presence of 1 Wₛ of uncompensated resistance has a narrow operating window between fully passive (−0.58 V) and voided deposition (−0.60 V). Deposition at −0.59 V (not shown) eventually passivates after 30 minutes at a height 13 μm below the field (y=0). An increase in the uncompensated resistance to of 11 Ωₛ allows for complete filling of the trench arrays similar to galvanostatic operation. The potentiostatic operating window is also much wider between full passivation (−0.64 V) and voided deposition (−1.02 V), examined in 20 mV increments.

Deposit profiles and interface contours for two potentiostatic conditions are shown in FIG. 23c, exhibiting similar behavior to the galvanostatic profiles in FIG. 23b. For the more reducing condition of −0.98 V, deposition proceeds uniformly across the array until the interface is near the field (y=0) at which point individual trenches begin to oscillate between passive and active states. It takes 45 min for all trenches to reach y=0 with about a 10 μm difference in height between the highest and lowest (trenches 1 and 4). Deposition at the less reducing condition of −0.72 V, on the other hand, exhibits uniform deposition across the array until a depth of −34 μm. At this point deposition localizes into select trenches, dynamically passivating and re-activating at different heights. Deposition across the interface becomes uniform when each trench approaches the field with a height of y=0 achieved for all features after 102 min.

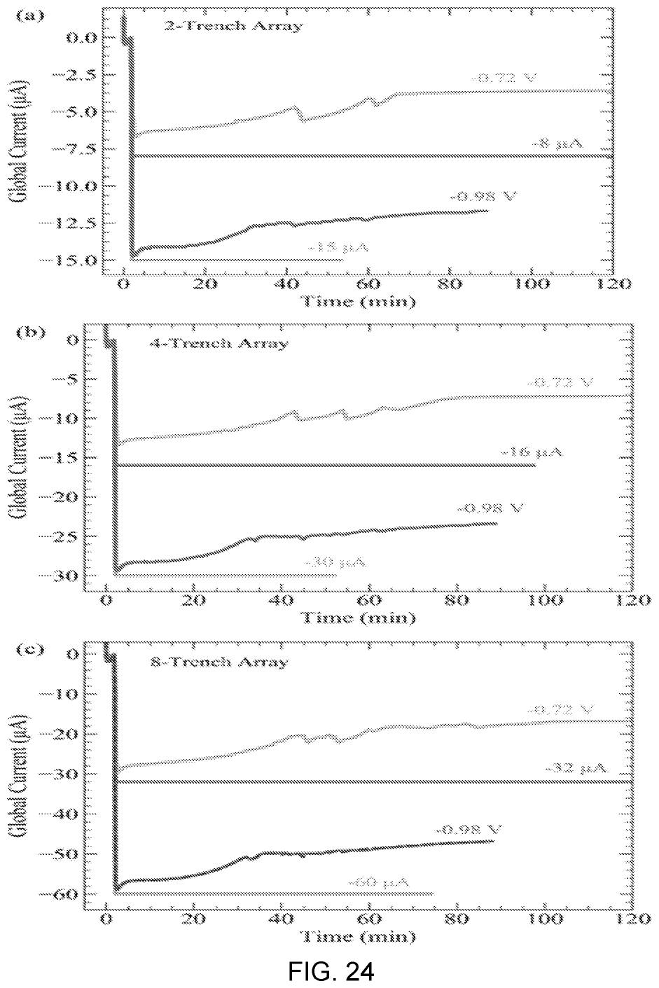

FIG. 24 shows the global constraint and response for select galvanostatic and potentiostatic conditions, respectively, for deposition in the 4 trench array depicted in FIG. 23 and for 2 trench and 8 trench arrays as well. For galvanostatic operation, similar filling behavior is achieved by scaling the applied current with the number of features or, more importantly, the surface area. Under potentiostatic control, the global current automatically adjusts for the increased surface area of larger arrays; the peak current at −0.98 V immediately after the pretreatment period shifts from −14.5 μA to −29 μA to −58 μA as trench quantity increases from an array of 2 to 4 to 8 trenches. In fact, the current profiles at −0.98 V fall directly on top of each other when scaling for the number of trenches, demonstrated by the dashed grey line in FIG. 24c representing the current profile at −0.98 V in a 4-trench array that has been doubled. Thus, a potentiostatic approach may be advantageous for depositing on wafers or dies with an unknown recessed surface area, dimensions, or number of features that vary experiment-to-experiment. Additionally, the noise associated with passivation of an individual trench at −720 mV is reduced for larger trench arrays; in a 2-trench array individual trench passivation accounts for 50% of the surface area versus only 12.5% in an 8-trench array.

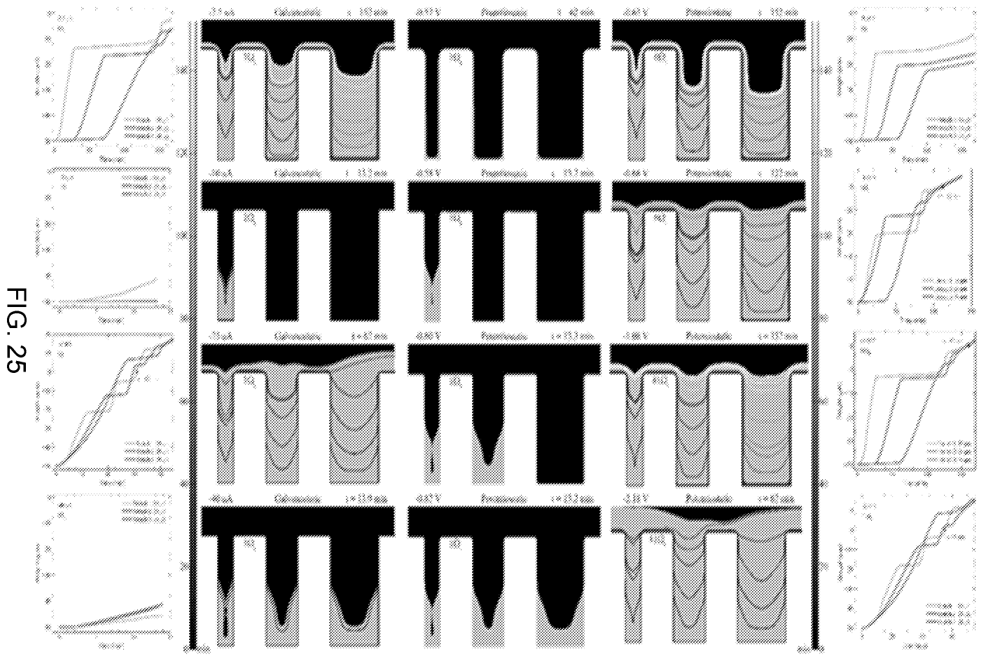

The influence of the control mode on copper deposition behavior is further explored in trench arrays of varying widths as shown in FIG. 25. Trench height and spacing is fixed at 50 μm and 30 μm, respectively, in a repeating array of 10 μm, 20 μm, and 30 μm wide features. In contrast to the uniform array in FIG. 23 and FIG. 24, galvanostatic simulations in a trench array with varying widths indicate a smaller and discontinuous operational window that results in void-free filling. Simulations at −5 μA produce conformal deposition on the electrode interface and, in 2.5 μA increments, deposition at −10 μA, −20 μA, and all currents greater than −30 μA result in void formation; two examples of voided deposition are shown in FIG. 25 at −10 μA and −40 μA. Void formation at the lower applied currents (i.e., −10 μA and −20 μA) is caused by localization of the majority of applied current to the narrowest trench. For applied currents greater than −30 μA, deposition occurs across the trench array but at a rate sufficient to deplete metal ion in the narrowest trench leading to void formation. Interestingly, all other conditions between −5 μA and −35 μA (again, in 2.5 μA intervals) produce fully filled trench arrays; two examples are also shown in FIG. 25 at −7.5 μA and −25 μA. For the less aggressive applied current value filling of each trench progresses individually: deposition occurs in trench 1 from 2 min to 25 min, trench 2 from 26 min to 70 min, and trench 3 from 71 min to 132 min. The local deposition on all three trenches slows after 155 min as the filling profile approaches the free surface with slightly varying heights across the array. Deposition at −25 μA occurs evenly across all three trenches until ≈10 min when the deposition rate accelerates in the smallest trench until it temporarily passivates at a height of −22 μm for about 20 min. This cycle of passivation and re-activation occurs once more before the deposit height reaches y=0. Deposition in trench 2 behaves similarly, cycling between passive and active but lagging behind trench 1, whereas trench 3 remains active until the deposit breaches the opening and passivates at a height of 8 μm. Interestingly, the smallest trench is the last to reach a height of y=0, occurring after 62 minutes of deposition. The overfill on the field is non-uniform similar to that observed for galvanostatic deposition in an array of identical trenches.

In an embodiment FIG. 25 shows simulated growth profiles for galvanostatic and potentiostatic copper electrodeposition at the indicated operating conditions, final times, and system resistances (1 Ωₛ, 6 Ωₛ, or 41 Ωₛ) in an array of trenches having varying widths: 10 μm, 20 μm, and 30 μm from left-to-right. Contour lines represent the position of the growth front, spaced in 10 min intervals and beginning after the pretreatment step, colorized to indicate time. Charts show the centerline position of the growth front of each individual trench (denoted as T1, T2, and T3 from left-to-right) as time progresses with annotations indicating the time at which all trenches reach y=0. Potentiostatic deposition with a range of system resistance values permits full seam-free and void-free filling that is impossible with potentiostatic deposition with smaller resistance and possible only in limited and non-contiguous ranges of applied current under galvanostatic conditions. The increased system resistance may be obtained using an external resistance, a semipermeable or permeable resistive baffle or membrane or increased separation between the reference and substrate.

Unlike galvanostatic deposition, or even potentiostatic deposition in a uniform array, simulations of potentiostatic deposition for the base case with 1 Wₛ results in either conformal deposition or voided filling in the varying width trench array in FIG. 25. At −0.57 V and applied potentials more positive, negligible deposition occurs and is largely conformal in nature. Deposition at applied potentials between −0.58 V and −0.605 V, in 5 mV intervals, produces a void in the narrowest trench while the 2^{nd} and 3^{rd} trenches remain passive. Simulations of deposition at −0.61 V and more negative potentials produce a fully activated trench array but with sufficient cupric ion depletion that a void forms in the narrowest trench. However, increasing the uncompensated resistance enables complete void-free filling of the varying width trench array. With a 6 Ωₛ of total uncompensated cell resistance deposition at potentials of −0.60 V and more positive values result in conformal deposition. Decreasing the applied potential to −0.63 V leads to iterative trench filling similar to the −7.5 μA galvanostatic condition except a transition to the passive state occurs for all 3 trenches after 100 min at heights of −15 μm, −20 μm, and −22 μm, respectively, from left to right. For a more reducing applied potential of −0.68 V, deposition occurs in trenches 1 and 2 initially while trench 3 remains passive, with all three trenches eventually reaching the field (y=0) after 112 min. With 6 Ωₛ of uncompensated resistance, voiding occurs at −0.64 V, similar to the −10 μA condition with localization of all current to trench 1, and at potentials more negative than −0.82 V.

Increasing the uncompensated cell resistance makes potentiostatic deposition behave more like galvanostatic deposition. With a 41 Ωₛ uncompensated resistance, the operating window between fully passive (−0.78 V) and voided fill (−2.38 V) is greatly widened. However, simulations within this range, in 100 mV increments, show intermediate potentials can produce voids similar to the galvanostatic conditions seen in FIG. 25; specifically at −1.18 V and −1.68 V for the present geometry. Simulations at a less aggressive applied potential of −1.08 V predict individual filling similar to −0.63 V with a 6 Ωₛ uncompensated resistance, however, interface passivation occurs higher in the trench and all individual trench heights eventually reach y=0 after 162 min with only minor height variation across the array. Deposition at a more reducing applied potential of −2.18 V initially exhibits more uniform growth across the trench array, with individual trench passivation occurring sequentially in order of increasing trench width. The time at which all trenches reach a height of y=0 is also reduced, occurring after 55 min of deposition. Unlike deposition at −1.08 V, there is about a 10 μm height variation across the array for this condition. The individual deposit height profiles for potentiostatic deposition at −2.18 V and galvanostatic deposition at −25 μA show similar characteristics. The global current at −2.18 V with a 41% s uncompensated resistance shows little variation, peaking at −29.3 μA shortly after the pretreatment step and gradually decaying to −27.7 μA after 1.5 h of deposition.

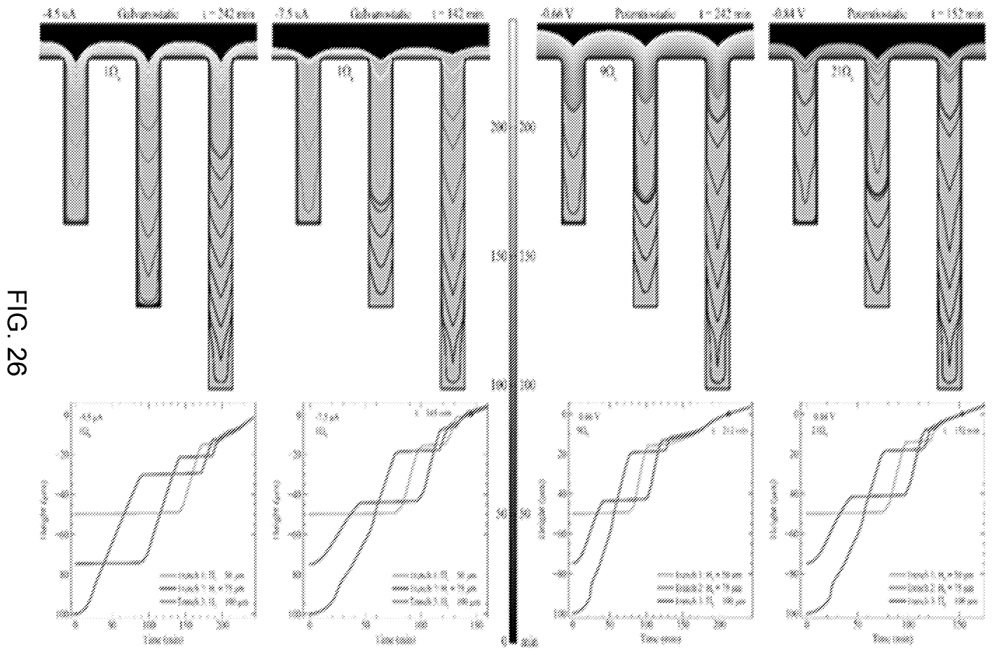

Copper deposition is further explored in an even more complex trench array of varying depths in FIG. 26; trench width and spacing is 10 μm and 20 μm, respectively, in a repeating array of 50 μm, 75 μm, and 100 μm deep features. Simulations of galvanostatic deposition predict fully filled trench arrays at conditions between −4 μA and −8 μA. Deposition at an applied current less than −4 μA results in conformal deposition or bottom-up fill that does not achieve a height of y=0 after 5 h while conditions more aggressive than −8 μA produce a void in the deepest trench. Simulations of deposition at the less reducing condition of −4.5 μA shows preferential filling of the deepest trench for the first 90 min before passivation occurs with a shift to deposition in the middle trench. After an additional 50 min a similar transition occurs with deposition shifting to the shallowest trench. After 220 min all three trenches are at approximately the same height, although still lower than the field at y=0. The filling profile is similar at −7.5 μA, except the applied current is sufficient to begin activating deposition in the middle trench immediately after the pretreatment step. Deposition in trenches 2 and 3 is sustained for 45 min and 75 min, respectively, before passivation. The shallowest trench remains passive for the first 80 min before significant filling occurs. As the deposit nears the trench outlet the differences in height lessen across the array. By 145 min there is minimal variation in trench height and all features have reached the position of the field (y=0). As expected, deposition at the more aggressive current of −7.5 μA achieves complete filling ≈100 min faster than −4.5 μA.

In another embodiment FIG. 26 shows simulated growth profiles for galvanostatic and potentiostatic copper electrodeposition at the indicated operating conditions, system resistances (1 Ωs, 9 Ωs, or 21 Ωs), and final times in a trench array of varying heights: 50 μm, 75 μm, and 100 μm from left-to-right. Contour lines represent the position of the growth front, spaced in 10 min intervals and beginning after the pretreatment step, colorized to indicate time. Charts show the centerline position of the growth front for each individual trench (denoted as T1, T2, and T3 from left-to-right) as time progresses with annotations indicating the time at which all trenches reach y=0. Galvanostatic as well as potentiodynamic control with the noted system resistance values achieve full seam-free and void-free filling. Filling in both cases starts first in the deepest features and progressively activates the next deepest features. Higher system resistance yields seam-free and void-free filling of all features nearly as fast as can be obtained with galvanostatic processing with a broad processing window. The increased system resistance may be obtained using an external resistance, a semipermeable or permeable resistive baffle or membrane or increased separation between the reference and substrate.

Similar to deposition in the other trench arrays (FIG. 23 and FIG. 25), potentiostatic deposition with only 1 Wₛ in uncompensated resistance cannot achieve a full filling of the array. The heights of each trench in the array at the most negative applied potential before voiding occurs are −49 μm, −57 μm, and −53 μm for increasing trench depth (not shown). The smallest value of uncompensated resistance that predicts a fully filled profile at a single applied potential is 9 Ωₛ (evaluated in 1 Ωₛ intervals) where complete filling occurs within 4 h at −0.66 V as shown in FIG. 26. Filling under these conditions has similarities to galvanostatic deposition at −7.5 μA; namely, deposition is initially localized to trenches 2 and 3 while trench 1 remains passive for the first 75 min. A significant portion of the feature filling time is associated with slower conformal deposition that occurs after ≈130 min, apparent in the closely spaced contours and thick deposit on the field. The centerline of the trenches only reaches the field (y=0) after 212 min. Increasing the total uncompensated cell resistance to 21 Ωₛ permits even faster filling of the trench array during potentiostatic operation at −0.84 V. Analogous to the 9 Ωₛ simulation, the shallowest trench remains passive for the first 75 min while deposition proceeds in the other two trenches. Finally, a shift to conformal deposition across the workpiece occurs after ≈130 min with a smaller height variation across the interface compared to that seen for the 9 Ωₛ simulation. The smaller remaining height for the final stage of conformal deposition enables the 21 Ωₛ simulation to achieve the y=0 threshold with only an additional 22 min (t=152 min) of deposition. For both the 9 Ωₛ and 21 Ωₛ uncompensated resistance examples shown in FIG. 26 deposition at potentials 20 mV more negative predict seam or void formation.

Bottom-up via and trench filling were shown for a variety of additive-derived S-NDR metal deposition systems. The simulations in the present work indicate that with appropriate optimization of the applied current, galvanostatic Cu deposition from a polyether—Cl⁻ suppressed CuSO₄—H₂SO₄ electrolyte can completely fill high-aspect ratio via and trench features for various dimensions. The same is true for potentiostatic conditions, however, filling under conditions where the uncompensated resistance is minimized often results in passivation before feature filling is complete. Different strategies have been explored to overcome this limitation that range from the use of potentiodynamic waveforms to increasing the uncompensated resistance of the electrochemical cell. The latter can be implemented in a number of ways, from judicious positioning of the reference electrode to insertion of a baffle that increases the effective resistivity of the electrolyte, to the addition of an external series resistor. The latter can be envisioned as a resistive contact on the working electrode in a 3-electrode system and, more generally, a series resistor located anywhere in a 2-electrode circuit. The current response to potentiostatic deposition in the S-NDR system with a significant uncompensated resistance begins to approach that for galvanostatic control. This not only helps establish conditions where complete feature filling is possible but also significantly broadens the processing window making the method more robust to variations in the workpiece geometry, from trench dimensions to patterning effects. Particularly interesting characteristics are captured for feature arrays of both uniform and variable dimensions where sequential filling of different sized features are predicted as well as oscillation between passivation and reactivation during filling under different conditions. Even more complex behavior can occur with discontinuities appearing in the processing window where periodic transitions between complete filling and void formation occur as the control parameter (potential or current) is increased linearly. All of the above reflect the strong path-dependent behavior expected for non-linear bifurcation reactions and further highlights the complex interactions in systems where a rapid electric response is globally coupled to slower, locally non-uniform, mass transport constrained, mixed control reactions such as evidenced in additive induced S-NDR systems.

The following are incorporated by reference herein in their entirety.
S-K. Kim, J. E. Bonevich, D. Josell and T. P. Moffat, “Electrodeposition of Ni in Sub-micrometer Trenches,” J. Electrochem. Soc., 154, D443-D451, (2007).
C. H. Lee, J. E. Bonevich, J. E. Davies and T. P. Moffat, “Magnetic Materials for 3-D Damascene Metallization: Void-free Electrodeposition of Ni and Ni70Fe30 Using 2-Mercapto-5-benzimidazole sulfonic Acid,” J. Electrochem. Soc., 155, D499-D507, (2008).
T. P. Moffat and D. Josell, “Extreme bottom-up superfilling of Through-Silicon-Vias by Damascene Processing: Suppressor disruption, positive feedback and Turing patterns,” J. Electrochem. Soc., 159, D208-D216, (2012).
D. Josell, D. Wheeler and T. P. Moffat, “Modeling Extreme Bottom-Up Filling of Through Silicon Vias, J. Electrochem. Soc., 159, D570-D576, (2012).
D. Wheeler, T. P. Moffat and D. Josell, “Spatial-temporal Modeling of Extreme Bottom-Up Filling of Through-Silicon-Vias,” J. Electrochem. Soc., 160, D3260-D3265, (2013).
D. Josell and T. P. Moffat, “Superconformal Electrodeposition in Complexed Alkaline Electrolyte, J. Electrochem. Soc., 161, D287-D292, (2014).
D. Josell and T. P. Moffat, “Bottom-Up Electrodeposition of Zinc in Through Silicon Vias,” J. Electrochem. Soc., 162, D129-D135, (2015).
D. Josell and T. P. Moffat, “Superconformal Bottom-Up Nickel Deposition in High Aspect Ratio Through Silicon Vias,” J. Electrochem. Soc., 163, D1-D10, (2016).
D. Josell, M. Siliva and T. P. Moffat, “Superconformal Bottom-Up Cobalt Deposition in High Aspect Ratio Through Silicon Vias,” J. Electrochem. Soc., 163, D809-D817, (2016).
D. Josell and T. P. Moffat, “Superconformal Bottom-Up Gold Deposition in High Aspect Ratio Through Silicon Vias,” J. Electrochem. Soc., 164, D327-D334, (2017).
D. Josell and T. P. Moffat, “Superconformal Copper Deposition in Through Silicon Vias by Suppression Breakdown,” J. Electrochem. Soc., 165, D23-D30, (2018).
T. M. Braun, S.-H. Kim, H.-J. Lee, T. P. Moffat, D. Josell, “Superconformal Nickel Deposition in Through Silicon Vias: Experiment and Prediction,” J. Electrochem. Soc., 165, D291-D300 (2018).
D. Josell and T. P. Moffat, “Bottom-up Filling of Damascene Trenches with Gold in a Sulfite Electrolyte,” J. Electrochem. Soc., 166, 1, D3022-D3034 (2019).
L. A. Menk, D. Josell, T. P. Moffat, E. Baca, M. G. Blain, A. Smith, J. Dominguez, J. McClain, P. D. Yeh and A. E. Hollowell, “Bottom-Up Copper Filling of Large Scale Through Silicon Vias for MEMS Technology,” J. Electrochem. Soc., 166, 1, D3066-D3071 (2019).
D. Josell, L. A. Menk, A. E. Hollowell, M. Blain and T. P. Moffat, “Bottom-Up Copper Filling of Millimeter Size Through Silicon Vias,” J. Electrochem. Soc., 166, D3254-D3258 (2019).
T. Braun, D. Josell, M. Silva, J. Kildon, T. P. Moffat, Effect of Chloride Concentration on Copper Deposition in Through Silicon Vias, J. Electrochem. Soc., 166, D3259-D3271 (2019).
T. M. Braun, D. Josell, J. John, and T. P. Moffat, “Simulations of Copper Electrodeposition in Through-Hole Vias,” J. Electrochem. Soc., 167, 013510 (2020). Editors' Choice
T. M. Braun, D. Josell, T. P. Moffat” Microelectrode Studies of S-NDR Copper Electrodeposition: Potentiodynamic and Galvanodynamic Measurements and Simulations,” J. Electrochem. Soc., 167, 082509 (2020).
T. M. Braun, D. Josell, S. Deshpande, J. John, T. P. Moffat, “Simulations of Copper Electrodeposition in Millimeter Size Through-Silicon Vias,” J. Electrochem. Soc., 167, 162508 (2020).
T. Braun, D. Josell and T. P. Moffat, “Simulating Cu Electrodeposition in High Aspect Ratio Features: Effect of Control Mode and Uncompensated Resistance in S-NDR Systems,” Electrochimica Acta, 375, 137925 (2021).

While one or more embodiments have been shown and described, modifications and substitutions may be made thereto without departing from the spirit and scope of the invention. Accordingly, it is to be understood that the present invention has been described by way of illustrations and not limitation. Embodiments herein can be used independently or can be combined.

Reference throughout this specification to “one embodiment,” “particular embodiment,” “certain embodiment,” “an embodiment,” or the like means that a particular feature, structure, or characteristic described in connection with the embodiment is included in at least one embodiment. Thus, appearances of these phrases (e.g., “in one embodiment” or “in an embodiment”) throughout this specification are not necessarily all referring to the same embodiment, but may. Furthermore, particular features, structures, or characteristics may be combined in any suitable manner, as would be apparent to one of ordinary skill in the art from this disclosure, in one or more embodiments.

All ranges disclosed herein are inclusive of the endpoints, and the endpoints are independently combinable with each other. The ranges are continuous and thus contain every value and subset thereof in the range. Unless otherwise stated or contextually inapplicable, all percentages, when expressing a quantity, are weight percentages. The suffix “(s)” as used herein is intended to include both the singular and the plural of the term that it modifies, thereby including at least one of that term (e.g., the colorant(s) includes at least one colorants). “Optional” or “optionally” means that the subsequently described event or circumstance can or cannot occur, and that the description includes instances where the event occurs and instances where it does not. As used herein, “combination” is inclusive of blends, mixtures, alloys, reaction products, and the like.

As used herein, “a combination thereof” refers to a combination comprising at least one of the named constituents, components, compounds, or elements, optionally together with one or more of the same class of constituents, components, compounds, or elements.

All references are incorporated herein by reference.

The use of the terms “a” and “an” and “the” and similar referents in the context of describing the invention (especially in the context of the following claims) are to be construed to cover both the singular and the plural, unless otherwise indicated herein or clearly contradicted by context. “Or” means “and/or.” Further, the conjunction “or” is used to link objects of a list or alternatives and is not disjunctive; rather the elements can be used separately or can be combined together under appropriate circumstances. It should further be noted that the terms “first,” “second,” “primary,” “secondary,” and the like herein do not denote any order, quantity, or importance, but rather are used to distinguish one element from another. The modifier “about” used in connection with a quantity is inclusive of the stated value and has the meaning dictated by the context (e.g., it includes the degree of error associated with measurement of the particular quantity).

What is claimed is:

1. A process for performing hysteretic current-voltage mediated void-free superconformal and bottom-up filling of recessed features of a substrate with a resistance member, the process comprising:
providing an electrodeposition composition comprising:
a metal electrolyte comprising a plurality of metal ions and a solvent; and
a suppressor disposed in the solvent; and
a hysteretic cyclic voltammogram;
providing the substrate comprising:
a field surface; and
a recess disposed in the substrate, the recess comprising a distal position and a proximate position relative to the field surface of the substrate;
exposing the recess to the electrodeposition composition;
potentiostatically or potentiodynamically controlling an applied electric potential of the recess with a potential wave form;
autonomously reducing, with the resistance member in presence of the electrodeposition composition with the hysteretic cyclic voltammogram, the deposition potential of the recess from that applied by the potential waveform;
bifurcating the recess into an active metal deposition region and a passive region in response to the deposition potential and ohmic variations of the substrate;
forming, in response to bifurcating the recess, a transition zone at an interface of the active metal deposition region and the passive region;
progressively moving the transition zone closer to the field surface and away from the distal position through the metal deposition; and
reducing the metal ions to form metal and depositing the metal in the active metal deposition region and not in the passive region; and
forming a resistance enhanced superconformal filling in the recess of the substrate from the metal in the active metal deposition region, the resistance enhanced superconformal filling being:
void-free,
disposed in the recess in the active metal deposition region from the distal position to the transition zone, and
absent in the passive region between the proximate position and the transition zone,
such that forming the resistance enhanced superconformal filling occurs in consequence of autonomously reducing the deposition potential of the recess with the resistance member in a presence of the hysteretic cyclic voltammogram of the electrodeposition composition.

2. The process of claim 1, wherein the resistance member is selected from the group consisting essentially of a lumped resistor, a baffle, and a selected interelectrode separation distance between the substrate and a reference electrode in electrical communication with the electrodeposition composition.

3. The process of claim 2, wherein the resistance member is the lumped resistor, and the lumped resistor comprises a resistor in electrical communication with and electrically interposed between the substrate and a counter electrode in electrical communication with the electrodeposition composition.

4. The process of claim 2, wherein the resistance member is the baffle, and the baffle is in fluid communication with and fluidically interposed between the substrate and the reference electrode.

5. The process of claim 1, wherein the resistance member is the selected interelectrode separation distance between the substrate and a reference electrode in electrical communication with the electrodeposition composition, and the process further comprises adjusting the interelectrode separation.

6. The process of claim 1, further comprising terminating the depositing the metal before completely filling the recess to the field surface.

7. The process of claim 1, further comprising terminating depositing the metal after completely filling the recess to the field surface.

8. The process of claim 1, wherein the hysteretic cyclic voltammogram comprises an S-shaped negative differential resistance.

9. The process of claim 1, wherein the metal ions comprise Fe²⁺, Fe³⁺, Pt²⁺, Pt⁴⁺, Ir³⁺, Ir⁴⁺, Rh³⁺, Pd²⁺, Co²⁺, Nᵢ²⁺, Au³⁺, Zn²⁺, Bi³⁺, Pb²⁺, Re⁷⁺, Au⁺, Ag⁺, Sn²⁺, W⁺, Mo⁶⁺, Cu²⁺, Cu⁺, or a combination comprising at least one of the foregoing metal ions, and
the metal comprises cobalt, gold, nickel, iron, silver, platinum, iridium, rhodium, palladium, rhenium, tungsten, molybdenum, tin, bismuth, zinc, lead, copper or a combination comprising at least one of the foregoing metals.

10. The process of claim 1, wherein the electrodeposition composition further comprises anions for the metal ions, the anions comprising sulfate, chloride, sulfite, perchlorate, bromide, citrate, tartrate, ethylenediamine, ethylenediaminetetracetic acid, or a combination comprising at least one of the foregoing anions.

11. The process of claim 1, wherein the suppressor comprises a polyether; a polyethylene oxide; a polyethylene glycol; a poloxamer; a poloxamine; alkylammonium cations, or a combination comprising at least one of the foregoing suppressors.

12. The process of claim 1, wherein the electrodeposition composition further comprises a leveler comprising an amine, a polyethyleneimine, a phenolphthalein, or alkylammonium cations; or a combination comprising at least one of the foregoing levelers.

13. The process of claim 1, wherein the electrodeposition composition further comprises chloride, bromide, or iodide.

14. The process of claim 1, wherein the recess comprises:
a depth from the field surface to the distal position that is from 10 nm to 900 μm, and
an aspect ratio from 1 to 70.

15. The process of claim 1, wherein the recess comprises a through hole, a blind hole, or a combination comprising at least one of the foregoing recesses.

16. The process of claim 1, wherein the potential wave form comprises a single fixed applied potential.

17. A system for performing hysteretic current-voltage mediated void-free superconformal and bottom-up filling of recessed features of a substrate with a resistance member, the system comprising:
a cell;
an electrodeposition composition disposed in the cell and comprising:
a metal electrolyte comprising a plurality of metal ions and a solvent; and
a suppressor disposed in the solvent; and
a hysteretic cyclic voltammogram;
the substrate disposed in the cell in fluid communication with the electrodeposition composition and comprising:
a field surface; and
a recess disposed in the substrate, the recess comprising a distal position and a proximate position relative to the field surface of the substrate, such the recess is in contact with the electrodeposition composition,
such that an applied electric potential of the recess is under potentiostatically or potentiodynamically control with a potential wave form;
the resistance member in communication with the electrodeposition composition and the substrate,
wherein the system is arranged and configured such that the resistance member in presence of the electrodeposition composition with the hysteretic cyclic voltammogram:
autonomously reduces the deposition potential of the recess from that applied by the potential waveform, such that the recess is bifurcated into an active metal deposition region and a passive region in response to the deposition potential and ohmic variations of the substrate; whereby, in response to bifurcating the recess, a transition zone is formed at an interface of the active metal deposition region and the passive region, such that the transition zone progressively moves closer to the field surface and away from the distal position through the metal deposition to reduce the metal ions and form metal to deposit the metal in the active metal deposition region and not in the passive region; thereby forming a resistance enhanced superconformal filling in the recess of the substrate from the metal in the active metal deposition region,
wherein the resistance enhanced superconformal filling is void-free, disposed in the recess in the active metal deposition region from the distal position to the transition zone, and absent in the passive region between the proximate position and the transition zone,
such that forming the resistance enhanced superconformal filling occurs in consequence of autonomously reducing the deposition potential of the recess with the resistance member in a presence of the hysteretic cyclic voltammogram of the electrodeposition composition.

18. The system of claim 17, wherein the resistance member is selected from the group consisting essentially of a lumped resistor, a baffle, and a selected interelectrode separation distance between the substrate and a reference electrode in electrical communication with the electrodeposition composition.

19. The system of claim 18, wherein the resistance member is the lumped resistor, and the lumped resistor comprises a resistor in electrical communication with and electrically interposed between the substrate and a counter electrode in electrical communication with the electrodeposition composition.

20. The system of claim 18, wherein the resistance member is the baffle, and the baffle is in fluid communication with and fluidically interposed between the substrate and the reference electrode.

21. The system of claim 17, wherein the resistance member is the selected interelectrode separation distance between the substrate and a reference electrode in electrical communication with the electrodeposition composition, and the process further comprises adjusting the interelectrode separation.

22. The system of claim 17, wherein the hysteretic cyclic voltammogram comprises an S-shaped negative differential resistance.

23. The system of claim 17, wherein the metal ions comprise Fe²⁺, Fe³⁺, Pt²⁺, Pt⁴⁺, Ir³⁺, Ir⁴⁺, Rh³⁺, Pd²⁺, Co²⁺, Nᵢ²⁺, Au³⁺, Zn²⁺, Bi³⁺, Pb²⁺, Re⁷⁺, Au⁺, Ag⁺, Sn²⁺, W⁶⁺, Mo⁶⁺, Cu²⁺, Cu⁺, or a combination comprising at least one of the foregoing metal ions, and
the metal comprises cobalt, gold, nickel, iron, silver, platinum, iridium, rhodium, palladium, rhenium, tungsten, molybdenum, tin, bismuth, zinc, lead, copper or a combination comprising at least one of the foregoing metals.

24. The system of claim 17, wherein the electrodeposition composition further comprises anions for the metal ions, the anions comprising sulfate, chloride, sulfite, perchlorate, bromide, citrate, tartrate, ethylenediamine, ethylenediaminetetracetic acid, or a combination comprising at least one of the foregoing anions.

25. The system of claim 17, wherein the suppressor comprises a polyether; a polyethylene oxide; a polyethylene glycol; a poloxamer; a poloxamine; alkylammonium cations, or a combination comprising at least one of the foregoing suppressors.

26. The system of claim 17, wherein the electrodeposition composition further comprises a leveler comprising an amine, a polyethyleneimine, a phenolphthalein, or alkylammonium cations; or a combination comprising at least one of the foregoing levelers.

27. The system of claim 17, wherein the electrodeposition composition further comprises chloride, bromide, or iodide.

28. The system of claim 17, wherein the recess comprises:
a depth from the field surface to the distal position that is from 10 nm to 900 μm, and
an aspect ratio from 1 to 70.

29. The system of claim 17, wherein the recess comprises a through hole, a blind hole, or a combination comprising at least one of the foregoing recesses.
